(19) United States
(12) Patent Application Publication
(10) Pub. No.: US 2007/0164352 A1
(43) Pub. Date: Jul. 19, 2007

(54) MULTI-BIT-PER-CELL NVM STRUCTURES AND ARCHITECTURE

(75) Inventors: Alvaro Padilla, Berkeley, CA (US); Tsu-Jae King, Fremont, CA (US)

Correspondence Address: JOHN P. O'BANION;O'BANION & RITCHEY LLP, 400 CAPITOL MALL SUITE 1550, SACRAMENTO, CA, 95814, US

(73) Assignee: THE REGENTS OF THE UNIVERSITY OF CALIFORNIA, Oakland, CA (US)

(21) Appl. No.: 11/609,846

(22) Filed: Dec. 12, 2006

Related U.S. Application Data
(60) Provisional application No. 60/749,735, filed on Dec. 12, 2005.

(51) Int. Cl. H01L 29/792; G11C 16/04

(52) U.S. Cl. 257/324; 365/185.01

(57) ABSTRACT

A transistor structure, such as a Double-gated FET (DG FET), that has been modified to include a charge-trapping region used to store either 2- or 4-bits of information. The charge-trapping region can, for example, be embedded in the gate dielectric stack underneath each gate electrode, or placed on the sidewalls of each gate electrode.

### CROSS-REFERENCE TO RELATED APPLICATIONS

This application claims priority from U.S. patent application Ser. No. 60/749,735 filed on Dec. 12, 2006, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

A portion of the material in this patent document is also subject to protection under the maskwork registration laws of the United States and of other countries. The owner of the maskwork rights has no objection to the facsimile reproduction by anyone of the patent document or the patent disclosure, as it appears in the United States Patent and Trademark Office publicly available file or records, but otherwise reserves all maskwork rights whatsoever. The maskwork owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to non-volatile memory (NVM) devices, and more particularly to NVM structures utilizing different charge storage and/or read mechanisms.

2. Description of Related Art

A conventional non-volatile memory (NVM) cell, which is shown in FIG. 1, is similar to the traditional transistor structure, except that its gate oxide is essentially modified to include a charge-trapping region, such as a Poly-Si film for a flash memory cell or a Si₃N₄ film for a SONOS structure, that is placed between a tunnel oxide (Ttₒₓ) and a control oxide (CTₒₓ) film.

Bit information is stored in this cell through the controlled placement of electrons onto its charge-trapping film. The charge stored in the charge-trapping region modulates the threshold voltage (V_{T}) of the transistor, and this modulation allows the identification of the presence of electrons, or lack thereof, stored in the charge-trapping region of the cell. In a single bit-per-cell structure, this V_{T} modulation results in two binary states: a state with a low V_{T} (binary state “1”), and a state with a high V_{T} (binary state “0”). For optimum performance, the separation between these two states (measured as ΔV_{T}) needs to be maximized so that the different states can be properly recognized; additionally, charge leakage from the charge-trapping film must be minimized so that the data stored in the cell is maintained as long as possible.

It will be appreciated that the explosive growth of the portable electronics industry has placed a strong demand on the availability of ultra-high density NVM devices. Traditionally, enhancement in NVM density has been achieved through the use of multi-bit architectures coupled with device scaling. However, current Si floating-gate memory devices are difficult to scale to gate lengths below 50 nm because of their large gate-stack equivalent oxide thickness (EOT). As an alternative, a SONOS (silicon-oxide-nitride-oxide-silicon) device has better scalability than a floating-gate device since charge is stored in discrete traps within the nitride region, thereby allowing for more aggressive scaling of its tunnel oxide. Still, a conventional SONOS memory device requires a substantially thicker EOT (˜10 nm) than a logic device (˜2 nm) thereby reducing electrostatic integrity, wherein scalability declines.

To further enhance storage density, multiple bits can also be stored within a single cell. The dual-bit storage scheme, based on charge-trapping in different regions of a single charge-trapping region, is currently used in conventional single-gate (e.g., NROM™ and MirrorBit™) SONOS NVM cells, and has been demonstrated in multi-gated SOI conventional SONOS FinFET cells. In these previous works, a conventional read method has been utilized in which charge is detected by measuring threshold voltage change in the cell in response to the charge stored on the bit next to the source electrode. These technologies are difficult to scale to sub-50 nm L_{g} since the metric of choice (e.g., the cell's V_{T}) is highly sensitive to short channel effects (SCE). Specifically, the drain-induced barrier lowering (DIBL) effect makes V_{T} of the cell sensitive to charge stored on the bit next to the drain electrode, and this sensitivity, which is normally referred to as the complementary bit disturb issue, affects the separation between programmed and erased states, and thus affects the scalability of the structure.

To ameliorate these effects, and thus achieve stable multi-bit storage in the nanoscale regime, bit-to-bit interference can be suppressed by physically separating the charge-trap sites. This can be performed in practice, for example, by adopting a NVM cell structure that utilizes gate-sidewall spacers to store charge.

FIG. 2 depicts the source junction located underneath the charge storage site when using the conventional read method on this cell design. It should be noted that in order to maximize the shift in V_{T} with charge storage at the source-side bit, a gate-underlapped structure is required in which the channel length L_{eff} is larger than the cell's gate length L_{g}. This requirement limits the potential scalability of this structure since its effective gate-length (L_{eff}) must be significantly larger than its actual gate-length (L_{g}).

As already mentioned, V_{T} of the transistor is used to identify the state information stored in a NVM cell. However, V_{T} as normally defined occurs in the linear region of the I_{ds}-V_{gs} curve, before saturation. It will be noted that the slope of the linear region is highly sensitive to the presence of charge anywhere within the gate stack, for example within the charge-trapping region, the silicon-gate oxide interface or the gate oxide. As a result, V_{T} of the cell is defined within a highly non-constant, variable region of the current-voltage (IV) curve and its measurement leads to significant cell-to-cell variation, especially when voltage stress conditions of the different cells are factored in.

Accordingly, a need exists for an NVM device structure that can provide scaling improvements while reducing read variations across the cells as outlined above. The present invention satisfies those needs, as well as others, and overcomes the deficiencies of previously developed non-volatile memory devices.

### BRIEF DESCRIPTION OF THE SEVERAL VIEWS OF THE DRAWING(S)

The invention will be more fully understood by reference to the following drawings which are for illustrative purposes only:

FIG. 1 is a schematic cross-section of a conventional NVM cell.

FIG. 2 is a schematic cross-section of a conventional single gate NVM cell with charge storage at the gate sidewalls.

FIG. 3 is a schematic cross-section of a single gate NVM cell with charge storage at the gate sidewalls for GIDL bit state reading according to an embodiment of the present invention.

FIG. 4A-4B are schematic cross-sections of multi-bit-per-cell dual-gate (DG) non-volatile memory (NVM) cell structures according to embodiments of the present invention.

FIG. 5 is a symbol reference used for either of the multi-bit-per-cell dual-gate (DG) non-volatile memory (NVM) cells of FIG. 4A-4B.

FIG. 6 is a graph of regions within the I_{ds}-V_{gs} curve in relation to threshold voltage V_{T} or the saturated I_{GIDL} current, according to an aspect of the present invention.

FIG. 7 is a schematic of a NOR-type “Virtual Ground SOI” array architecture according to an aspect of the present invention, showing row and column decoders.

FIG. 8 is a symbol reference used for the multi-bit-per-cell non-volatile memory (NVM) cells of FIG. 7.

FIG. 9 is a cross-sectional view in the XZ plane of the multi-bit-per-cell dual-gate (DG) non-volatile memory (NVM) cell structure according to an embodiment of the present invention.

FIG. 10 is a cross-sectional view in the YZ plane of the multi-bit-per-cell dual-gate (DG) non-volatile memory (NVM) cell structure of FIG. 9.

FIG. 11 is a top view of an array of the multi-bit-per-cell dual-gate (DG) non-volatile memory (NVM) cells which were shown in FIG. 9-10.

FIG. 12 is a graph of drain-source current with response to gate voltage (IV curve) for programmed and erased states utilizing a conventional read sense mechanism.

FIG. 13 is a graph of I_{GIDL} with response to gate voltage (IV curve) for the programmed and erased states according to an aspect of the present invention.

FIG. 14 is a schematic of a NAND-type “Virtual Ground in SOI” array architecture according to an aspect of the present invention.

FIG. 15 is a symbol reference used for the two-bit-per-cell non-volatile memory (NVM) cells of FIG. 14.

FIG. 16 is a perspective view of the dual-bit FinFET SONOS memory device according to an embodiment of the present invention.

FIG. 17 is a side view of the dual-bit FinFET SONOS memory device of FIG. 16 shown in the YZ plane.

FIG. 18 is a side view of the dual-bit FinFET SONOS memory device of FIG. 16 shown in the XZ plane.

FIG. 19 is a top view of an array of dual-bit FinFET SONOS memory cells, which were shown in FIG. 16.

FIG. 20 is a graph of drain-source current for the programmed and erased states for cells according to an aspect of the present invention, showing the state of cells A, B, C and D as shown in FIG. 14.

FIG. 21 is a schematic of an equivalent read circuit according to an aspect of the present invention.

FIG. 22 is a graph of Log(I_{DS}) with respect to gate voltage according to a GIDL read means according to an aspect of the present invention.

FIG. 23 is a graph of Log(I_{DS}) with respect to gate voltage according to a combined read means according to an aspect of the present invention.

FIG. 24 is a perspective view of an embodiment of dual-bit FinFET memory cell structure according to an aspect of the present invention.

FIG. 25 is a top view of the dual-bit FinFET memory cell structure of FIG. 24.

FIG. 26 is a schematic of a four bit dual-gate NVM structure according to an aspect of the invention, showing the bits and gates in relation to the drain-source fin element.

FIG. 27 is a schematic of a dual-gate NVM structure according to an aspect of the invention, showing the symmetry of the structure.

FIG. 28 is a graph of individual front-gate (FG) and back-gate (BG) biasing according to an aspect of the present invention.

FIG. 29 is a schematic of an NOR-type architecture utilizing four-bit dual-gate NVM cells according to an aspect of the present invention.

FIG. 30 is a symbol reference used for the four-bit-per-cell non-volatile memory (NVM) cells of FIG. 29.

FIG. 31 is a schematic cross-section of a dual-gate ADG NVM structure according to an aspect of the present invention, showing the XZ plane view.

FIG. 32 is a schematic cross-section of a dual-gate ADG NVM structure according to an aspect of the present invention, showing the YZ plane view.

FIG. 33 is a schematic top view of a NOR-type layout using the dual-gate ADG NVM structures of FIG. 31.

FIG. 34 is a schematic of an NAND-type architecture utilizing four bit dual-gate NVM cells according to an aspect of the present invention.

FIG. 35 is a symbol reference used for the four bit-per-cell non-volatile memory (NVM) cells of FIG. 34.

FIG. 36 is a schematic of a four bit dual-gate NVM cell according to an aspect of the present invention.

FIG. 37 is a graph of VI for the erased and programmed states on a bit being read by conventional threshold method.

FIG. 38A-38M are schematics of steps within a fabrication process flow according to an aspect of the present invention.

FIG. 39 is a schematic of a single gate NVM cell having multiple charge retention regions according to an aspect of the present invention.

FIG. 40 is a schematic of a structure utilized for simulating the cell structure of FIG. 39.

FIG. 41 is a graph of Log(I_{DS}) with respect to gate voltage for a two bit single-gate SW FET according to an aspect of the present invention, showing the use of PolySi as the charge-trapping material.

FIG. 42 is a graph of Log(I_{DS}) with respect to gate voltage for a two bit single-gate SW FET according to an aspect of the present invention, showing the use of Si₃N₄ as the charge-trapping material.

FIG. 43-44 are schematic views of bit states and grouping of two bits within a memory cell according to an aspect of the present invention.

FIG. 45 is a graph of Log(I_{DS}) with respect to gate voltage for a two bit double-gate FET according to an aspect of the present invention.

FIG. 46 is a graph of Log(I_{DS}) with respect to front to rear gate voltage for a two bit double-gate FET according to an aspect of the present invention.

FIG. 47-48 are schematic views of a first of two distinct groups of states for a four bit-per-cell ADG FET according to an aspect of the present invention.

FIG. 49 is a graph of Log(I_{DS}) with respect to the front gate voltage for a two bit double-gate FET according to an aspect of the present invention.

FIG. 50-51 are schematic views of a second of two distinct groups of states for a four bit-per-cell ADG FET according to an aspect of the present invention.

FIG. 52 is a graph of Log(I_{DS}) with respect to the back gate voltage for a two bit double-gate FET according to an aspect of the present invention.

FIG. 53-54 are schematic views of two distinct groups of states for bit 1 of a four bit-per-cell ADG FET according to an aspect of the present invention.

FIG. 55 is a graph of Log(I_{DS}) with respect to bit 1 for a two bit double-gate FET according to an aspect of the present invention.

FIG. 56-57 are schematic views of two distinct groups of states for bit 4 of a four bit-per-cell ADG FET according to an aspect of the present invention.

FIG. 58 is a graph of Log(I_{DS}) with respect to bit 4 for a two bit double-gate FET according to an aspect of the present invention.

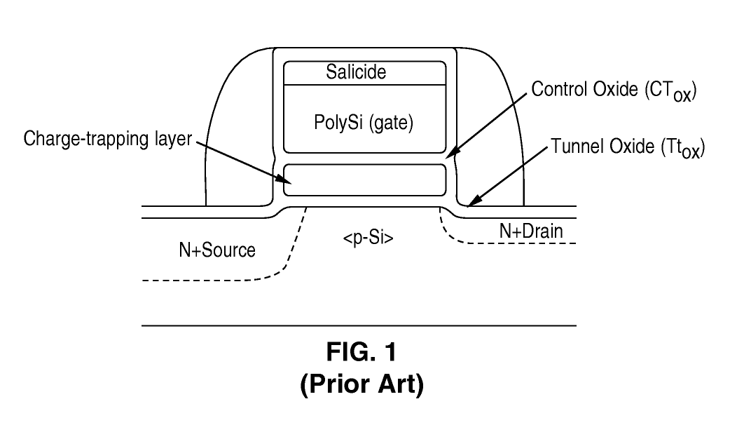

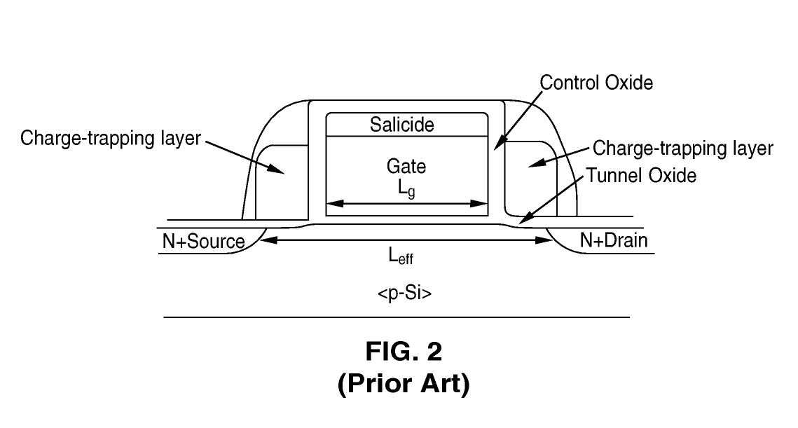

### BRIEF SUMMARY OF THE INVENTION

Non-volatile memory structures are described which can store multiple bits of information while mitigating against readability variation. The structures increase sensitivity to charge which is specifically stored in the trapping region, and reduce sensitivity to charge stored elsewhere within the gate stack of the transistor and which arises in a saturated region of the current-voltage (IV) curve. In general terms, the invention is a transistor structure, such as a Double-gated FET (DG FET), that has been modified to include a charge-trapping region used to store either two or four bits of information. The invention is applicable to thin-body transistor structures, single-gate bulk-Si transistor structures, and other transistor structures.

Implementation is described according to two general approaches, and variations thereof. The first approach involves the use of a new charge storage detection metric which is very sensitive to charge localized within a specific region of the NVM cell and which is substantially insensitive to charge stored elsewhere in the cell. The second approach involves the use of novel (thin-body) transistor structures that achieve beneficial electrostatic integrity without the requirement for maintaining a thin gate-dielectric stack. A double-gate thin-body transistor structure, such as the FinFET structure, is described which can achieve desirable subthreshold swing levels (e.g., 60 mV/decade at room temperature) and accordingly scalability.

An aspect of this invention involves the use of a novel charge detection method that is very sensitive to charge stored on the bit next to the drain electrode, and which is less sensitive to short-channel effects (SCE). This novel read method can be used in both single-gate and multi-gate NVM cells.

Another aspect of this invention involves the use of a novel single-gate transistor structure modified to include charge-trapping regions embedded on the sidewalls of the gate electrode, and with source and drain doping extensions included underneath the sidewall spacers (e.g., wherein effective channel length L_{eff} is approximately equal to gate length L_{g}). Due to the (gate-overlapped) design of this novel structure, the novel charge detection method is utilized to detect charge storage at either charge-trapping site.

Another aspect of the invention is a double-gated thin-body transistor structure modified to include charge-trapping regions configured to store either two bits or four bits of information. In one embodiment, the charge-trapping region is embedded within the gate dielectric stack underneath each gate electrode. In another embodiment, the charge-trapping region is embedded on the sidewalls of each gate electrode. In either embodiment, the structure includes symmetric gates to achieve two or four bits per cell. The structure also comprises an undoped silicon film with thickness Tₛᵢ and gate-length L_{g}, and the charge-trapping region comprises a material that has the ability to store charge. In these structures, the gate oxide underneath the charge-trapping region has a thickness sufficiently thin to allow for tunneling of electrons or holes from the silicon film onto the charge-trapping region, or from the charge-trapping region onto the silicon film at low operating voltages. In the conventional read mode, the structure utilizes a change in on-state current to distinguish the uncharged state of the bit next to the source electrode. In the novel read mode, a change in the off-state current is used to distinguish the uncharged state of the bit next to the drain electrode.

In one embodiment, the transistor structure has at least one gate electrode, and at least one charge-trapping region configured to store a bit of information, wherein an off-state current is utilized to distinguish charge state of said bit in said transistor structure. In one mode, a bit state in the transistor structure is determined by off-state current, and a change in off-state current is utilized to determine a change in charge state of a bit in the charge-trapping region. In one mode, a change in the off-state current arises from a change in transverse electric field due to stored charge.

In one embodiment, the transistor structure has one or more charge-trapping regions configured for storing 2 bits of information. In one embodiment, the transistor structure comprises a single-gate transistor structure. In one embodiment, the single-gate has a pair of sidewalls, and the charge-trapping regions are located along each of said sidewalls.

In one embodiment, the at least one charge-trapping region is configured for storing 4 bits of information. In one embodiment, the transistor structure comprises a plurality of gate electrodes. In one embodiment, the at least one charge-trapping region is embedded in a gate dielectric stack underneath each gate electrode. In one embodiment, each gate electrode has a pair of sidewalls and charge-trapping regions are located along each of said sidewalls of each gate electrode. In one embodiment, the transistor structure includes symmetric double gates. In one embodiment, the transistor structure includes asymmetric double gates. In one embodiment, the transistor structure comprises an undoped or lightly doped silicon film with thickness Tₛᵢ and the double-gates have gate-length L_{g}. In one embodiment, the transistor structure includes an oxide layer underneath each charge-trapping region and the oxide layer has a thickness sufficiently thin to allow for tunneling of electrons or holes from the silicon film into the charge-trapping region or from the charge-trapping region into the silicon film at relatively low voltages.

In another embodiment, the transistor structure has at least one gate electrode and at least one charge-trapping region, the at least one gate electrode and the at least one charge-trapping region are configured for storing 2 bits of information, and an off-state current is utilized to distinguish charge state of said bit in said transistor structure. In one mode, a bit state in the transistor structure is determined by off-state current and a change in off-state current is utilized to determine a change in charge state of a bit in the charge-trapping region. In one mode, a change in the off-state current arises from a change in transverse electric field due to stored charge. In one embodiment, the transistor structure comprises a single-gate transistor structure. In one embodiment, each gate electrode has a pair of sidewalls and charge-trapping region is located along each of said sidewalls.

In another embodiment, the transistor structure comprises at least one gate electrode and at least one charge-trapping region, the said at least one gate electrode and said at least one charge-trapping region are configured for storing 4 bits of information, and an off-state current is utilized to distinguish charge state of said bit in said transistor structure. In one mode, a bit state in the transistor structure is determined by the transistor off-state current and a change in off-state current is utilized to determine a change in charge state of a bit in the charge-trapping region. In one mode, a change in the off-state current arises from a change in transverse electric field due to stored charge. In one embodiment, the transistor structure comprises a plurality of gate electrodes. In one embodiment, the said at least one charge-trapping region is embedded in a dielectric stack underneath each gate electrode. In one embodiment, each gate electrode has sidewalls and the said at least one charge-trapping region is embedded along each of said sidewalls. In one embodiment, the transistor structure includes symmetric double gates. In one embodiment, the transistor structure includes asymmetric double gates. In one embodiment, the transistor structure comprises an undoped or lightly doped silicon film with thickness Tₛᵢ and the gate electrodes have gate-length L_{g}. In one embodiment, transistor structure includes an oxide layer underneath each charge-trapping region, and the oxide layer has a thickness sufficiently thin to allow for tunneling of electrons or holes from the silicon film into the charge-trapping region or from the charge-trapping region into the silicon film at relatively low operating voltages.

In another embodiment, the transistor structure comprises at least one charge-trapping region and a plurality of gate electrodes, the said at least one charge-trapping region and said plurality of gate electrodes are configured for storing 4 bits of information, and an off-state current is utilized to distinguish charge state of said bit in said transistor structure. In one mode, a bit state in the transistor structure is determined by off-state current and a change in off-state current is utilized to determine a change in charge state of a bit in the charge-trapping region. In one mode, a change in the off-state current arises from a change in transverse electric field due to stored charge. In one embodiment, the transistor structure comprises a gate dielectric stack underneath each gate electrode. In one embodiment, the said at least one charge-trapping region is embedded in said gate dielectric stack underneath each gate electrode. In one embodiment, each gate electrode has a pair of sidewalls and the said at least one charge-trapping region is located along each of said sidewalls of each gate electrode. In one embodiment, the transistor structure includes symmetric double gates. In one embodiment, the transistor structure includes asymmetric double gates. In one embodiment, the transistor structure comprises an undoped or lightly doped silicon film with thickness Tₛᵢ and the gate electrodes have gate-length L_{g}. In one embodiment, the transistor structure includes an oxide layer underneath each charge-trapping region and the oxide layer has a thickness sufficiently thin to allow for tunneling of electrons or holes from the silicon film into the charge-trapping region or from the charge-trapping region into the silicon film at relatively low operating voltages.

In one embodiment, the transistor structure comprises a double-gated field effect transistor having a gate dielectric stack and gate electrodes. In one embodiment, the charge-trapping region is embedded in the gate dielectric stack underneath each gate electrode. In another embodiment, the charge-trapping region is embedded on the sidewalls of each gate electrode. In one embodiment, the structure includes symmetric gates to achieve 2 bits per cell. In another embodiment, the structure includes asymmetric gates to achieve 4 bits per cell. In one embodiment, the structure comprises an undoped silicon film with thickness Tₛᵢ and gate-length L_{g}. In one embodiment, the charge-trapping region comprises a material that has the ability to store charge. In another embodiment, the structure includes gate oxide underneath the charge-trapping region, and the gate oxide has a thickness sufficiently thin to allow for tunneling of electrons or holes from the silicon film onto the charge-trapping region or from the charge-trapping region onto the silicon film at low operating voltages. In one mode, the structure utilizes a change in off-state current to distinguish the (un)charged state of the bit.

Further aspects and embodiments of the invention will be brought out in the following portions of the specification, wherein the detailed description is for the purpose of fully disclosing preferred embodiments of the invention without placing limitations thereon.

### DETAILED DESCRIPTION OF THE INVENTION

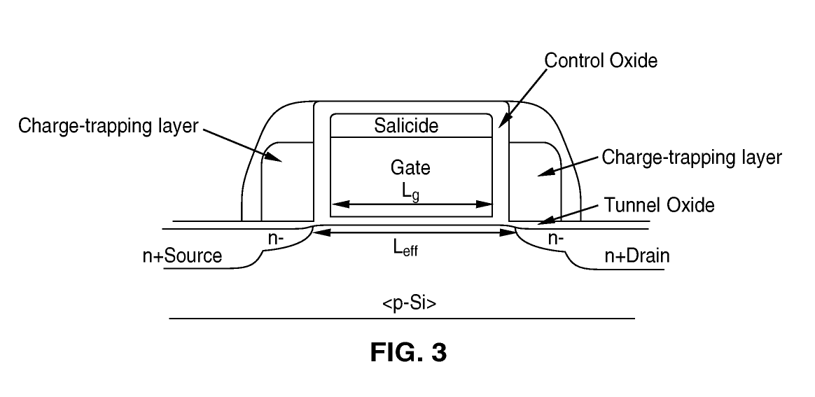

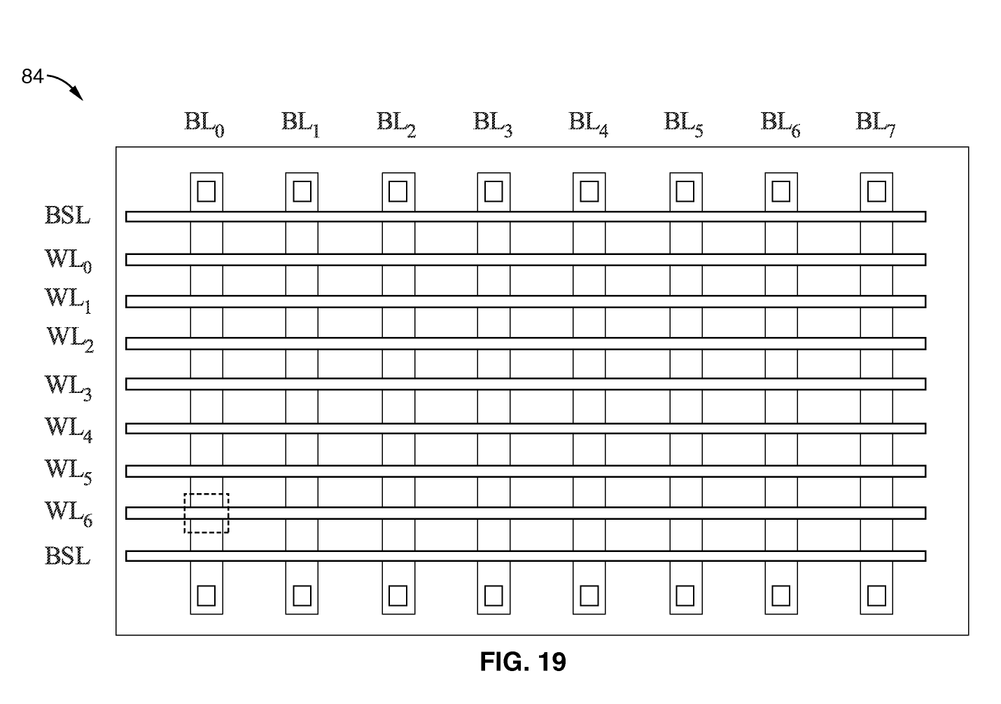

Referring more specifically to the drawings, for illustrative purposes the present invention is embodied in the apparatus generally shown in FIG. 3 through FIG. 58. It will be appreciated that the apparatus may vary as to configuration and as to details of the parts, and that the method may vary as to the specific steps and sequence, without departing from the basic concepts as disclosed herein.

FIG. 3 illustrates an embodiment of the invention in which a single-gated NVM transistor structure has been modified to include charge-trapping regions embedded within the gate-sidewall spacers. Due to the symmetry of this cell, the proposed structure can be used to store two bits of information. To enhance the scalability of this cell, the novel charge detection method is utilized on this structure since this charge detection method is less susceptible to SCE, and the conventional read detection method cannot readily be used on this novel cell design. For that reason, a single-gated NVM structure with lightly doped (“LDD”) extensions on both the source and drain electrodes (making its effective channel length L_{eff} roughly equal to gate length L_{g}) can also be implemented and used with this novel charge detection method.

For optimum performance and ease of manufacturability, a preferred embodiment of this single-gate structure utilizes both a thin gate oxide film and thin junction edges (Xⱼ) at the lightly-doped extensions of both the source and drain electrodes, with dimensions chosen accordingly to minimize short-channel effects (SCE). The charge-trapping film can be any material that has the ability to store charge (e.g., PolySi, silicon-rich nitride, or HfO₂, or similar).

For optimum programming or erasing of the device, in a preferred embodiment the thickness of the gate oxide underneath the charge-trapping region (Ttₒₓ) should be thin enough (˜3 nm) to allow for tunneling of electrons or holes from the silicon film onto the charge-trapping region (or vice versa) at low operating voltages. In addition, the thickness of the control oxide film CTₒₓ (that isolates the gate electrode from the charge-trapping sites) should be sufficiently thick to mitigate any programming or erase disturbances.

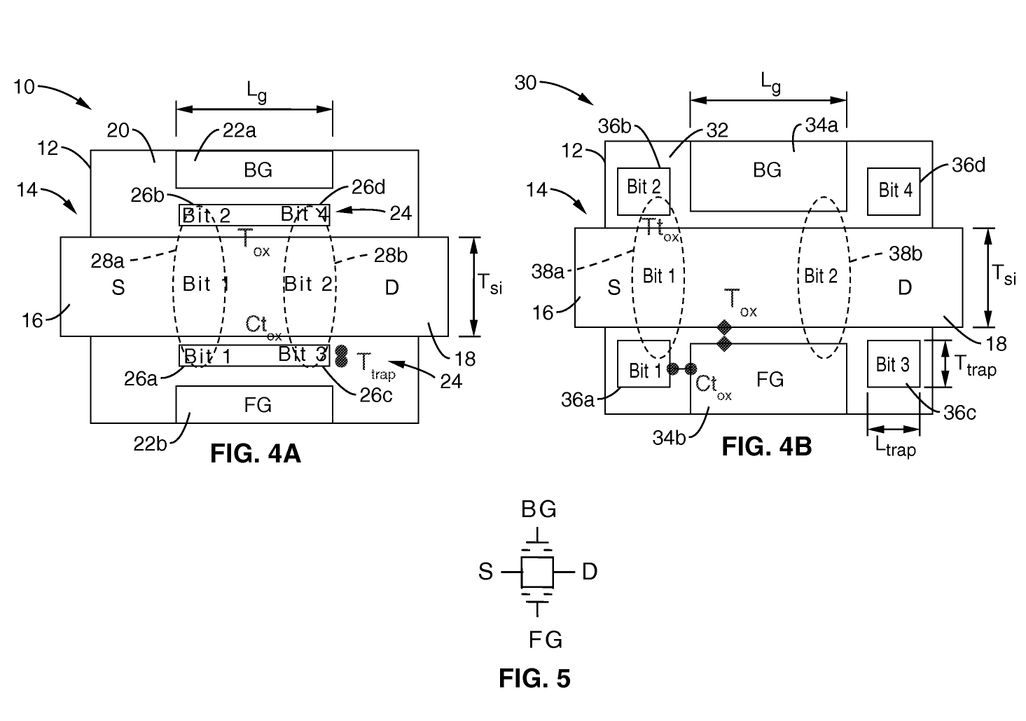

FIG. 4A-4B illustrates an example embodiment 10 in which a double-gated thin-body transistor structure has been modified to include charge-trapping regions used to store either two or four bits of information. As shown in the figures the structures comprise a double-gated FET (DG FET) with the charge-trapping region either embedded in the gate dielectric stack underneath each gate electrode as in the SONOS-like cell of FIG. 4A, or proximal to the sidewalls of each gate electrode as in FIG. 4B. The SONOS-like structure of FIG. 4A generally simplifies manufacturing. The structure of FIG. 4B does not require a large gate oxide layer, wherein it benefits from a substantially thinner EOT increasing scalability toward very short gate lengths. It should be noted that the ‘gate oxide layer’ in this case refers to the thickness of the gate-dielectric stack underneath each gate electrode. In the case of a conventional SONOS the gate oxide layer preferably consists of multiple layers, such as three layers (e.g., oxide-nitride-oxide, or “ONO”). In the novel (non-SONOS) structure of FIG. 4B, the gate oxide layer consists of only one layer (e.g., oxide). Thus, since the novel structure consists of only one ‘oxide’ film, its effective oxide thickness (EOT) is thinner than that of the conventional cell, even when the gate oxide thickness of the latter is thicker.

In FIG. 4A a SONOS-like NVM transistor structure 10 is shown with buried-oxide layer 12 upon which are fabricated fin 14 with a source region 16 and a drain region 18. A back gate 22a and front gate 22b are shown parallel to fin 14. A charge-storage film 24 is embedded within a silicon oxide dielectric film 20 on either side of fin 14 between gates 22a, 22b. Bit regions 26a-26d (Bits 1-4 respectively) are shown on charge storage film 24 for a four-bit cell. Bit regions 28a-28b are shown in relation to fin 16 for a two-bit cell. It should be noted that these bit regions are representative only, with Bit 1 formed on the left-hand side next to the source, and Bit 2 on the right-hand side next to the drain, the actual bits being stored in the charge-trapping regions and not within the silicon fin structure.

In FIG. 4B a NVM transistor structure 30 is shown with the charge storage areas placed at the sidewalls. Buried-oxide layer 12 is shown again having fin 14 with source region 16 and drain region 18. A back gate 34a and front gate 34b are shown parallel to fin 14. It will be noted that the gates are thicker than in the device of FIG. 4A In this case the gates only appear thicker because the charge-trapping region and control oxide films have been removed from underneath each gate electrode and are placed “on the sidewalls” of the structure (thereby providing additional ‘space’ for the gates. In reality, both structures may have the same physical dimensions at their gates. A charge-storage film 36a-36d is embedded within a silicon oxide dielectric film 32 which is shown adjacent the ends of the gates on either side of fin 14 which forms corresponding bit regions (Bits 1-4 respectively). Bit regions 38a-38b are shown proximal fin 16 between the respective portions of the charge-storage film to comprise a two-bit cell.

FIG. 5 illustrates by way of example a symbol used herein for representing the NVM structures shown in FIG. 4A-4B.

The NVM structure may incorporate symmetric gates as shown in FIG. 4A-4B. Both gates may comprise n⁺ PolySi, however, it should be appreciated that other materials, such as p⁺ PolySi (typically used as gate electrode in conventional transistor structures), may also be used at both gates. However, in this embodiment both gates utilize the same material to maintain the symmetry of the structure. It should be appreciated that the resulting symmetry of the structure allows for the treatment of each bit-line in an array layout as either a source or drain electrode, depending on the location of the bit that needs to be read, programmed or erased.

Using cell symmetry to store multiple bits has been demonstrated by researchers on a SONOS SOI FET structure. However, without the charge detection mechanism taught herein, the approach has a number of drawbacks. The use of the charge-detection method taught herein allows a symmetrical structure to be fabricated which attains improved scalability, less variability, and has the capability to retain multiple bits of storage within the cell.

Symmetric gates (e.g., n⁺ PolySi gates) may also be utilized in a four bit cell according to an implementation of the present invention. Thus, because of its symmetry with respect to the source and drain electrodes and both of the gates, this structure is able to store four bits per unit cell.

For optimum performance and ease of manufacturability, a preferred embodiment of the NVM structure comprises an undoped silicon film with thickness Tₛᵢ and gate-length L_{g}. The dimensions of the structure are chosen accordingly to minimize short-channel effects (SCE). The charge-trapping film may comprise any material having the ability to store charge (e.g., PolySi, silicon-rich nitride, HfO₂, and so forth). For optimum programming or erasing of the device, in a preferred embodiment the thickness of the gate oxide underneath the charge-trapping region (Ttₒₓ) should be sufficiently thin, such as ˜3 nm, to allow the tunneling of electrons or holes from the silicon film onto the charge-trapping region, or conversely from the charge-trapping region onto the silicon film, at low operating voltages. It should be noted that in the case above, “optimum” relates to both speed and power dissipation. Therefore, an optimum programming (or erase) method refers to that method which can program (or erase) the cell at the fastest rate (for speed), while utilizing the lowest possible voltages (mitigating power dissipation).

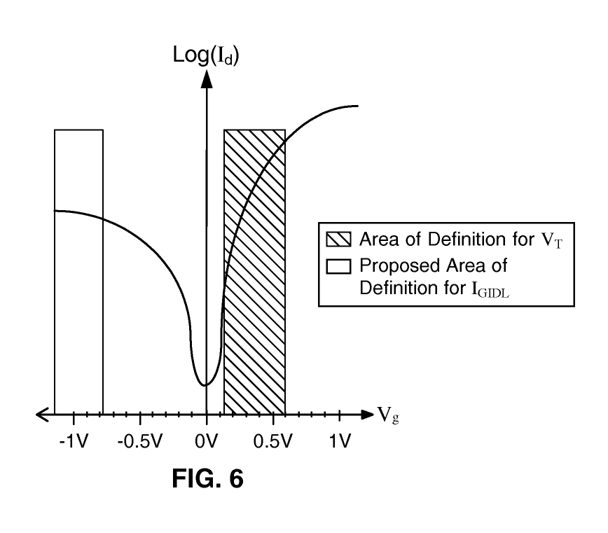

FIG. 6 depicts an IV curve showing a conventional threshold sense region in the rectangular area shown on the right side and an I_{GIDL} sense region in the rectangular area shown on the left side. The I_{GIDL} sensing utilizes a change in the off-state of the transistor (e.g., gate-induced drain leakage, or “GIDL”) current to distinguish the uncharged state of the bit adjacent to the drain electrode. This change in off-state current arises from the change in the transverse electric field due to the charge stored at that site. Due to the symmetry of the structure, with respect to the source and drain electrodes, this method of charge detection is applicable to both single-bit or multi-bit NVM cells.

Principles of Operation

A. Two-Bit-Per-Cell Operation

1. NOR-Type Virtual Ground in SOI Array Architecture:

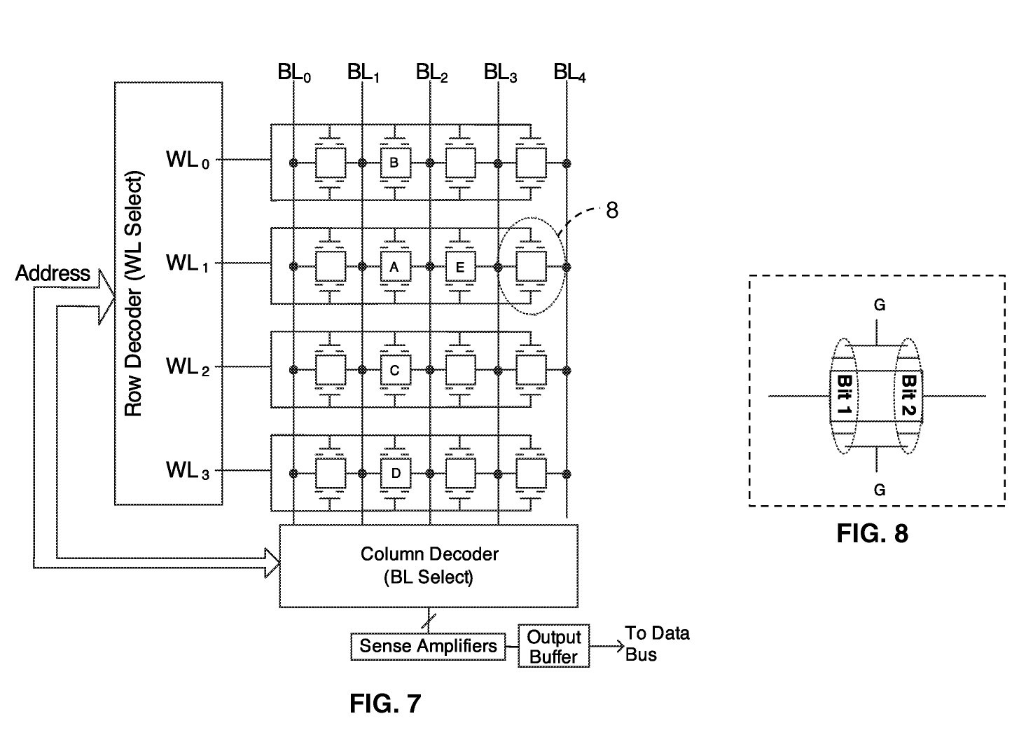

FIG. 7 illustrates a circuit diagram of a NOR-type array architecture that utilizes a double-gated NVM FET (e.g., cells shown in FIG. 4A or FIG. 4B or similar) as its unit cell. In this architecture, cells are arranged in a two-dimensional (2D) array, where the gates of all cells in the same row are connected to the same word-line (WL), and all the source (or drain) electrodes of all cells in the same column are connected to the same bit-line (BL).

FIG. 8 depicts a symbol for the NVM cell marked as a two-bit unit cell.

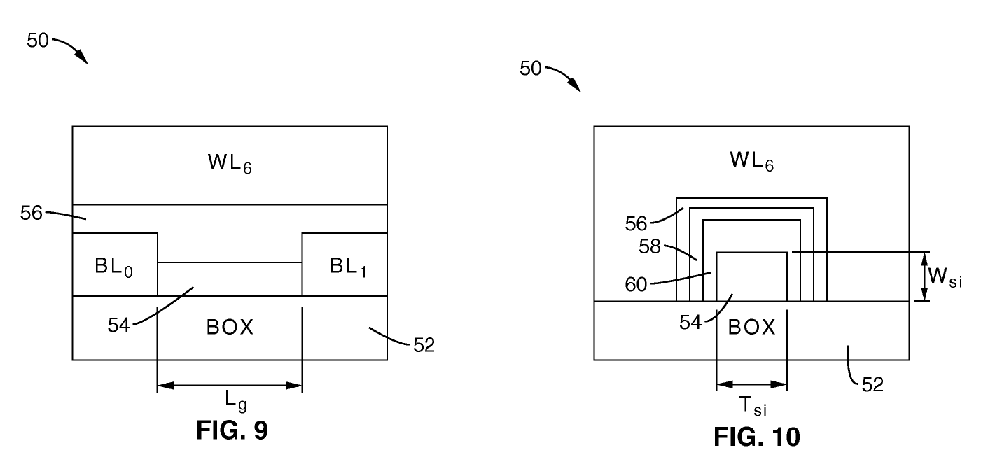

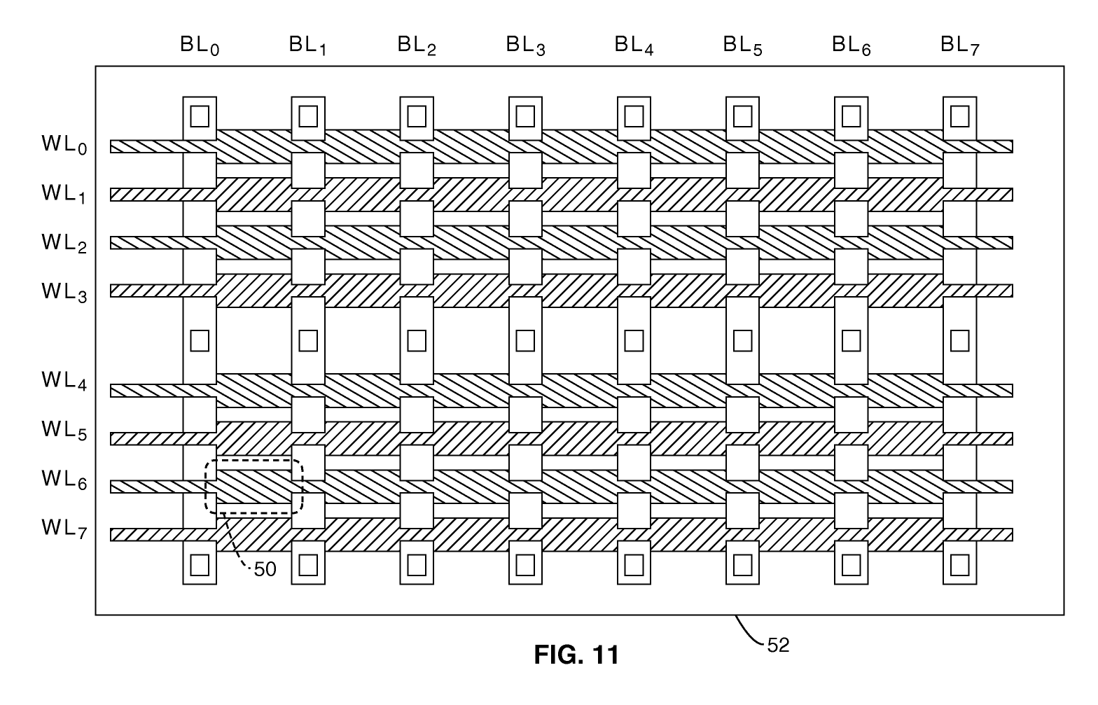

FIG. 9 through FIG. 11, illustrate an embodiment 50 of the cell structure (FIG. 9-10) and an example array configuration (FIG. 11) for the NOR-type array architecture of FIG. 7. FIG. 9 depicts an XZ plane view of cell 50 while FIG. 10 is a YZ plane view of cell 50. FIG. 11 illustrates a layout (not to scale) in which an array of cells 50 are interconnected to word and bit lines.

The NVM array structure of FIG. 11 is fabricated on a silicon on insulator (“SOI”) material, which lies on top of a buried oxide (“BOX”) substrate 52, upon which bit lines BL₀-BL₇ are formed. The FinFET NVM cell 50 is formed on a p-type silicon on insulator (SOI) wafer, where silicon is (epitaxially) grown on top of a buried oxide (“BOX”) film 52 (hence, the term “SOI”). The fin 54 is made of p-type silicon, and bit-lines BL₀, BL₁ also comprise silicon, except that these are doped with n-type impurities, such as phosphorus, to make them “n-type”. The gate oxide film 60 preferably comprises silicon dioxide (SiO₂) in this embodiment, and the charge-trapping region 58 is by way of example silicon nitride (Si₃N₄), although alternative charge-trapping material may be utilized. A silicon dioxide film (SiO₂) 56 is used to isolate the charge-trapping film 58 from the word-line WL₆, which is made of n⁺ PolySi material (as an example).

Operating conditions are shown in Table 1 to read, program, and erase a specific bit (e.g., bit 1 of cell ‘A’ in FIG. 7) in the array utilizing the conventional read (bit state threshold sending), program (hot electron injection (HEI)) and erase (hot hole injection (HHI)) methods. Table 2 lists the operating voltages required to read, program, and erase the complementary bit (e.g., bit 2) of the same cell within the array by these conventional methods. As shown, this architecture uses SOI technology, and the unit cell in this architecture utilizes a DG SONOS NVM FinFET cell structure according to an embodiment of the invention (although the architecture applies to both structures shown in FIG. 4A-4B). This architecture utilizes symmetry to treat each bit-line as a source or drain electrode as necessary and thus attain two bits of storage in every cell. This approach has been successfully utilized in fabricating a planar “virtual ground” NROM architecture to achieve two bits per cell. However, one significant difference between these two architectures lies in the method(s) used to read the bit information stored in each cell, as discussed below.

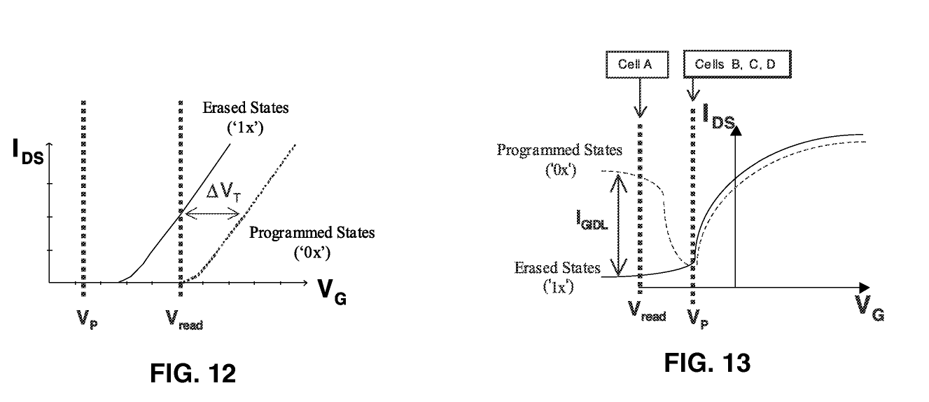

FIG. 12 depicts an IV curve utilizing a conventional read threshold detailing source-drain current in response to gate voltage for both erased and programmed states and denoting the voltages applied to the selected (“V_{read}”) and non-selected (“Vₚ”) word-lines (WL) required to read the bit next to the source electrode (Bit 1) on the selected cell (e.g., cell ‘A’ in FIG. 7). To read cell ‘A’ in FIG. 7 by this method, the gate electrodes connecting to this cell are biased to a positive bias (V_{read}), while a moderate drain-to source voltage (V_{ds}) is applied between both bit-lines (BL) connecting to this structure. To mitigate leakage current from unselected cells, all cells within the same column, but different rows (e.g., cells B, C, D) are turned off completely to mitigate any leakage current arising from these cells through application of a small negative bias “V_{P}” to the word-lines connecting to their gates. Additionally, cells within the same row, but different columns (e.g., cell E) are turned off by setting their applied V^{DS} voltage to ˜0 Volts. Table 2 shows operating voltages when utilizing the conventional read threshold sensing method in the NOR-type architecture.

FIG. 13 depicts an IV curve for I_{GIDL} threshold sensing which utilizes a change in the off-state current of the transistor to detect charge storage on the bit next to the drain electrode. Curves are shown for the erased and programmed states and denoting the voltages applied to the selected (“V_{read}”) and non-selected (“Vₚ”) word-lines (WL) required to read the bit next to the drain electrode (Bit 2) on the selected cell (e.g., cell ‘A’ in FIG. 7). It is clearly seen in this graph the wide margin between programmed and erased states. Table 3 outlines operating voltages for I_{GIDL} threshold sensing of cell state within the NOR-architecture.

2. NAND-Type Virtual Ground in SOI Array Architecture:

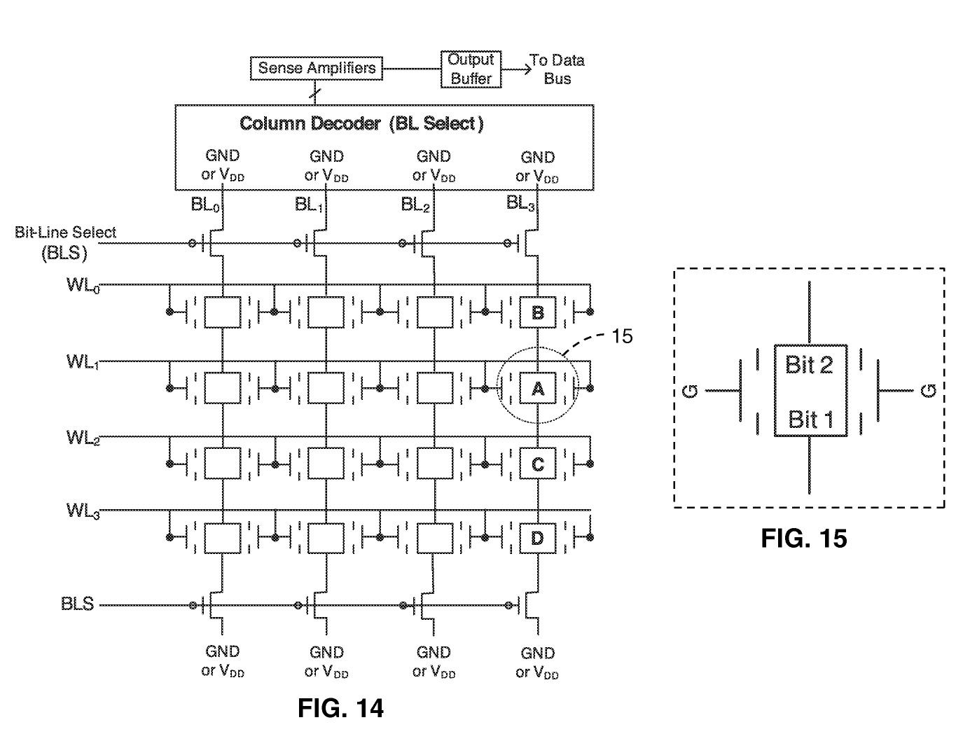

FIG. 14 shows a circuit diagram of a NAND-type array architecture that utilizes a double-gated NVM FET (such as the FinFET SONOS NVM cell) as its unit cell. In this architecture, cells belonging to the same bit-line are connected in series between two bit-line select (BLS) transistors, which must each be able to pass a high voltage (V_{DD}) as well as a low voltage (GND) to allow for forward-read as well as reverse-read operation of each cell.

FIG. 15 depicts a symbol for the two-bit cell used in FIG. 14.

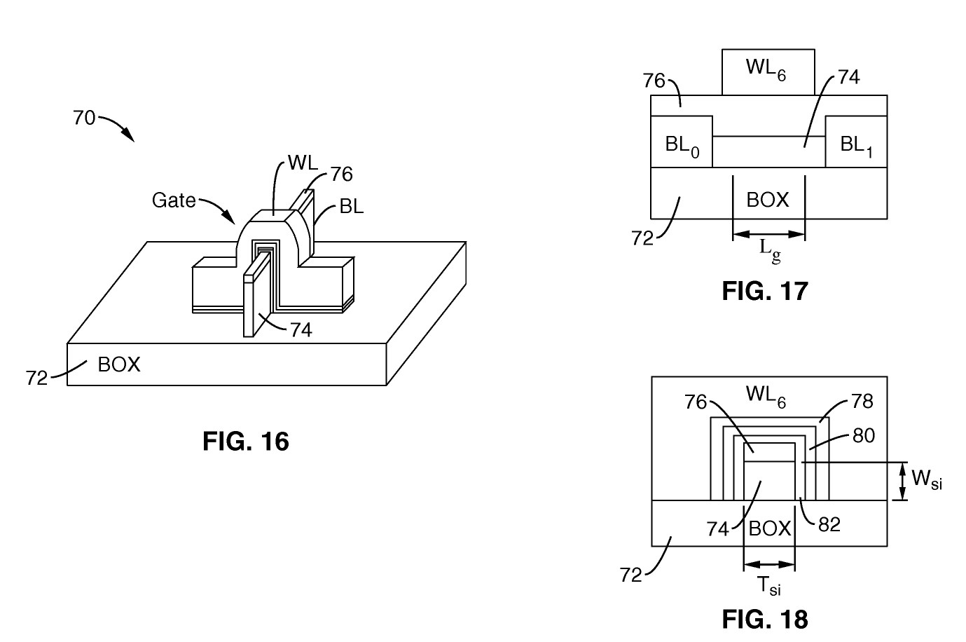

FIG. 16-19 shows a basic layout (not to scale) of an embodiment 70 of a cell structure (with planar cross-sections) of the unit cell and a NAND-type array architecture 84. As shown, this architecture uses SOI technology, and the unit cell in this architecture is the DG SONOS NVM FinFET cell structure according to an embodiment of the invention, although the architecture applies to structures shown in FIG. 4A-4B.

A SOI substrate, which lies on top of a BOX layer 72 is used to form each NVM FinFET cell 70. In this embodiment, fin 74 comprises p-type silicon, while bit-lines BL₀, BL₁ also comprise silicon which is doped with n-type impurities, such as phosphorus, to make them “n-type”. In this double-gated structure, the top of fin 74 is further isolated from the word-line with a thick silicon dioxide film 76, which provides a hard-mask in the manufacturing process of the cell. By way of example, the gate oxide film 82 comprises silicon dioxide (SiO₂), and the charge-trapping region 80 comprises silicon nitride (Si₃N₄). A silicon dioxide film (SiO₂) 78 is used to isolate the charge-trapping film 80 from the word-line WL₆, which by way of example may comprise a n⁺ PolySi material,

3. Conventional Read Method w/NOR-Type Architecture:

The state of the bit nearest to the source electrode of the selected cell is determined by application of a moderate drain-to-source voltage V_{ds} (e.g., 1.0V), while the gate electrodes are biased to a positive voltage V_{read} (about 0.5V). It will be noted that cell state consists of two possibilities: 1x or 0x, where “x” represents any potential binary state in the complementary bit, next to the drain electrode. With these settings, significant I_{DS} current will flow through the selected cell if there is no charge stored at that site, as shown in FIG. 12. A sense amplifier then detects the current, and the bit information stored in that site is thus identified. In an embodiment of the NOR-type “Virtual Ground NOR-type Architecture” of the present invention, all unselected cells belonging to the same column, but different rows are turned off completely, in order to minimize any leakage current from these cells, through application of a small negative bias (“V_{P}”) on their gates (FIG. 12). Also, a low drain-to-source voltage V_{ds} (about 0V) is applied to all cells located within the same row as the selected cell to minimize current arising from cells.

4. Novel Read Method w/NOR-Type Architecture:

Table 3 lists the operating conditions required to selectively read (via the novel method), program (via the conventional HEI method) and erase (via the conventional HHI method) a specific bit (e.g., bit 2 of cell ‘A’ in FIG. 7) within the NOR-type array. In this novel read method, the state of the bit nearest to the drain electrode of the selected cell is determined by application of a moderate V_{ds} (e.g., 1.5V), while the gate electrodes are biased to a negative voltage V_{read} (about −1.5V). Using these setting the graph of FIG. 13 shows significant I_{DS} current (mainly, GIDL current) will flow through the selected cell if there is charge stored at that site. In an embodiment of the NOR-type “virtual Ground NOR-type Architecture” of the present invention, all unselected cells belonging to the same column but different rows must be turned off completely, to minimize any leakage current arising from these cells, through application of a small negative bias (“V_{P}”) on their gates. The value of V_{P} should be that which minimizes I_{DS} current from these gates.

5. Conventional Read Method w/NAND-Type Architecture:

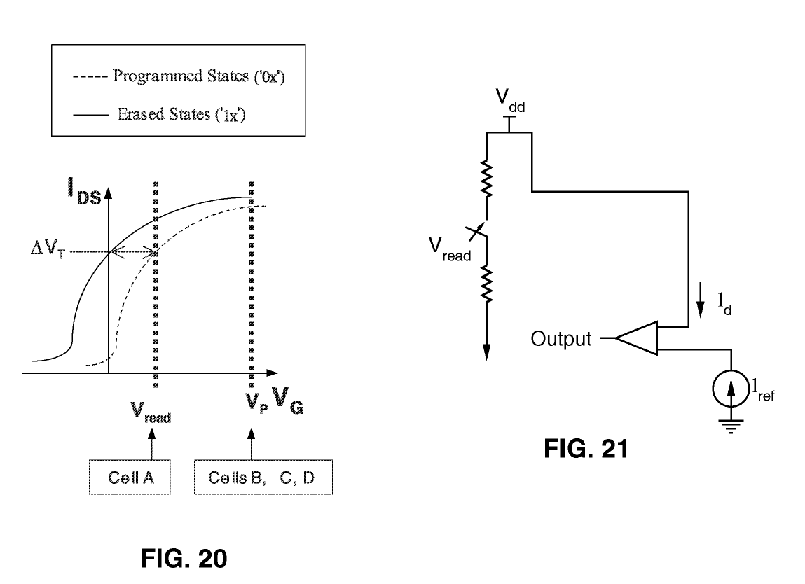

Table 4 lists the operating conditions required to selectively (a) read utilizing the conventional read threshold method, (b) program utilizing the conventional HEI method, and (c) erase utilizing the conventional FN Tunneling method, a specific bit (e.g., bit 2 of cell ‘A’ in FIG. 14) within the NAND-type array. The state of the bit nearest to the source electrode of the selected cell is determined by application of a moderate drain-to-source voltage V_{ds} (e.g., 1.5V), while the gate electrodes are biased to a positive voltage V_{read} (e.g., approximately 0.5V) that maximizes the separation in threshold voltage (ΔV_{T}) between the programmed and erased states. With these settings, significant I_{DS} current will flow through the selected cell only if there is no charge stored at that site (FIG. 20). In an embodiment of the NAND-type “Virtual Ground Architecture” of the present invention, all unselected cells belonging to the same column must be turned on completely, wherein they function as pass transistors regardless of the bit information stored in them, in response to the application of a positive bias (“V_{P}”) on their gates (FIG. 20). The value of V_{P}, however, should not so large as to create potential read disturbances. The equivalent circuit shown in FIG. 21 results from the bias conditions as shown, wherein current will flow through the series resistances if the selected switch is closed (e.g., if there is significant on-state current arising from the selected cell). A sense amplifier then detects the current, and the bit information stored in that site is thus identified.

6. Novel Read Method w/NAND-Type Architecture:

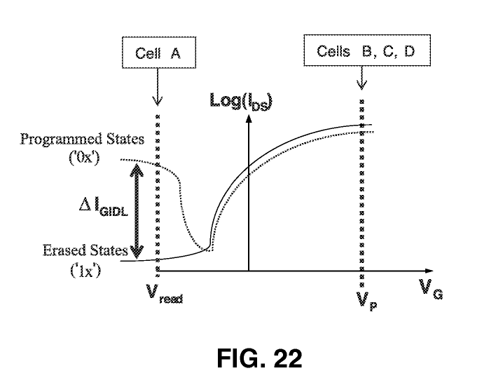

Table 5 lists the operating conditions required to selectively (a) read utilizing the novel read method, (b) program utilizing the conventional HEI method, and (c) erase utilizing the conventional FN Tunneling method, a specific bit (e.g., bit 2 of cell ‘A’ in FIG. 14) within the NAND-type array. The state of the bit nearest to the drain electrode of the selected cell (two possibilities: x0 or x1, where “x” represents any potential state in the complementary bit, next to the source electrode) is determined by application of a moderate V_{ds} (e.g., 1.5V), while the gate electrodes are biased to a negative voltage V_{read} (about −1.5V). With these settings, significant I_{DS} current (mainly, GIDL current) will flow through the selected cell only in response to a charge being stored at that site, such as seen in the IV graph of FIG. 22. In an embodiment of the NAND-type “Virtual Ground’ Architecture” of the present invention, all unselected cells belonging to the same column must be turned on completely through application of a positive bias (“V_{P}”) on their gates (FIG. 22). The completely turned on transistors function as pass transistors regardless of the bit information stored in them. The value of V_{P}, however, should not be so large as to create potential read disturbances. The equivalent circuit shown in FIG. 21 results from these bias conditions, wherein current flows through the series resistances if the selected switch is closed (e.g., if there is significant GIDL current arising from the selected cell). A sense amplifier then detects the current, and the bit information stored in that site is thus identified.

7. Combined Read Method w/NAND-Type Architecture:

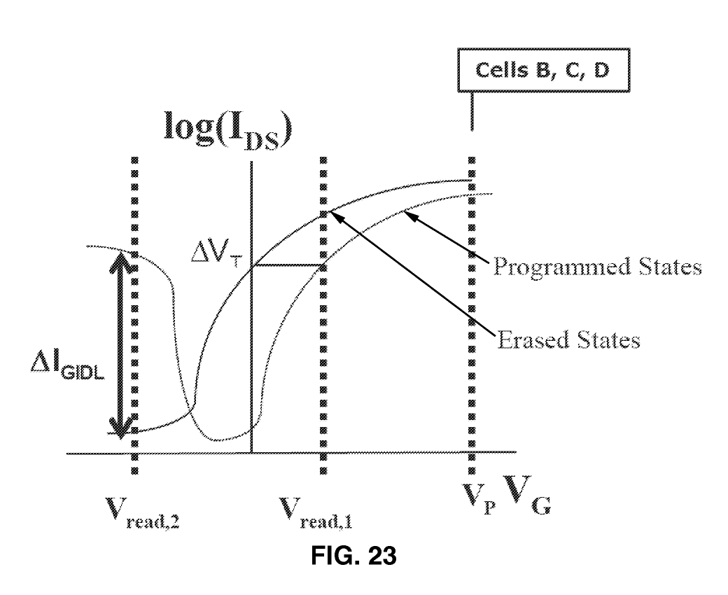

Both bits of the same cell may also be read with a single forward read. In this approach, the conventional read method is used to detect charge storage on the bit next to the source electrode, while the novel read method is used to detect charge storage on the bit next to the drain electrode. Thus, the state of both bits of the cell is determined through application of a moderate V_{ds} voltage (e.g., 1.5V), while a positive (or negative) voltage is applied to the gate electrodes to determine the state of the bit next to the source (or drain) electrode. Table 6 lists the operating conditions required to selectively read each bit (Bit 1 via the conventional read method, and Bit 2 via the novel read method) of cell ‘A’ within the NAND-type array of FIG. 14. In an embodiment of the NAND-type “Virtual Ground Architecture” of the present invention, all unselected cells belonging to the same column must be turned on completely, wherein these transistors act as pass transistors regardless of the bit information stored in them, through application of a positive bias (“V_{P}”) on their gates (FIG. 23). The value of V_{P}, however, should not be so large that it leads to potential read disturbances. The equivalent circuit described in FIG. 21 results from these bias conditions, wherein current will flow through the series resistances if the selected switch is closed (e.g., if there is significant on-state or off-state current arising from the selected cell). A sense amplifier then detects the current, and the bit information stored in that site is thus identified.

8. Program:

Each bit can be independently programmed via hot electron injection (HEI) in a manner similar to that used for the sidewall nonvolatile memory device reported in M. Fukuda, T. Nakanishi and Y. Nara, “New Nonvolatile Memory with Charge-Trapping Sidewall,” IEEE EDL, Vol. 24, No. 8, p. 490 (2003), incorporated herein by reference in its entirety. To write a bit, the gate and drain electrodes are each biased to a high voltage (≦5V), while the source is grounded.

9. Erase:

Each bit can be independently erased via hot hole injection (HHI). To erase the bit next to the drain electrode, the drain is biased to a high voltage and the source is grounded to generate holes next to the drain electrode either via impact ionization or band-to-band tunneling (BTBT). To direct the generated holes towards the charge-trapping region, the gate electrodes are biased to a large negative voltage. Alternatively, the two bits can be simultaneously erased via electron FN tunneling by simultaneously biasing the drain and source to the same high voltage while both gates are biased to a large negative voltage. Note that P. Xuan et al. has demonstrated that hot holes could be readily generated to erase a FinFET SONOS device without a body contact.

b. Two-Bit-Per-Cell Process Flow

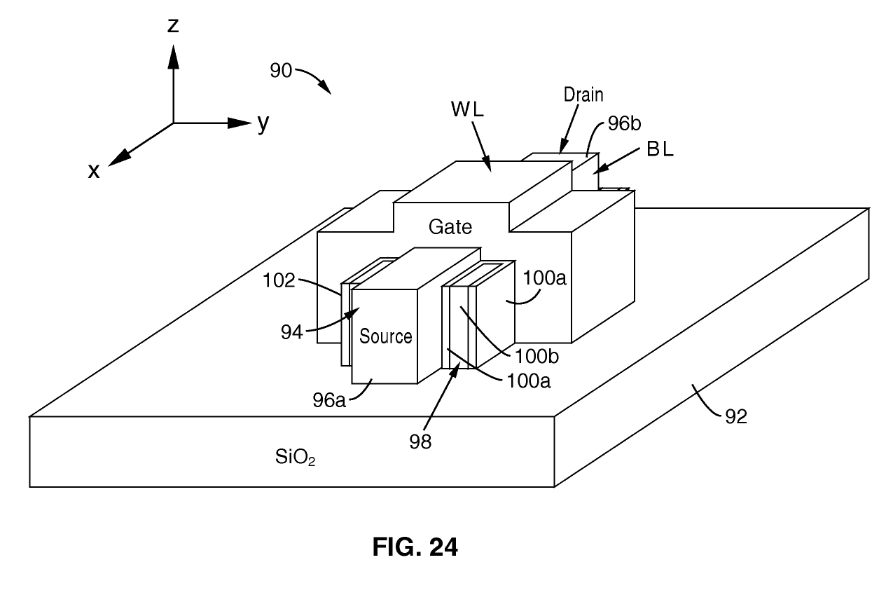

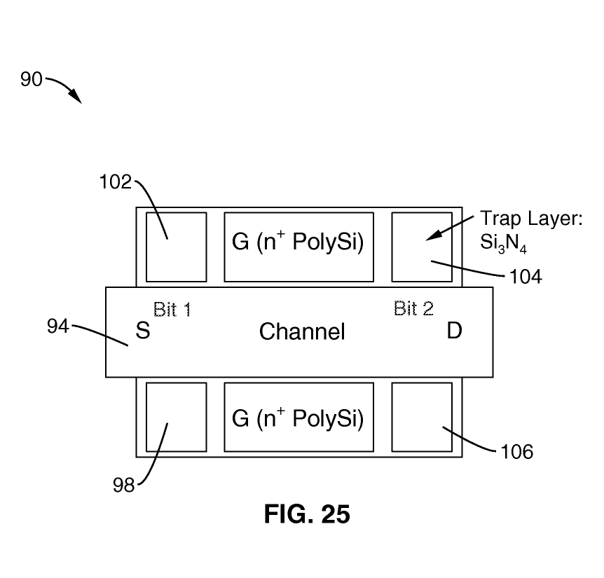

FIG. 24-25 shows an embodiment of a dual-bit FinFET cell structure with the charge-storage film (silicon-rich nitride) located at the sidewalls according to the present invention.

A SOI substrate, which lies on top of a BOX layer 92 is used to form this novel NVM FinFET cell 90. The materials and processes for embodiment 90 are described by way of example, and not limitation. Fin 94 comprises p-type silicon, with source electrode 96a and drain electrode 96b comprising silicon doped with n-type impurities, such as phosphorus, to make them “n-type”. The source 96a and drain 96b electrodes of the cell are connected to the memory array bit-lines (BL). This structure contains four ONO gate-dielectric stacks (98, 102, 104, and 106), each stack containing a tunneling silicon dioxide (SiO₂) film 100a, which isolates a silicon nitride (Si₃N₄) charge-trapping region 100b. A silicon dioxide (SiO₂) film 100a is used to isolate each charge-trapping film 100bfrom the (n+ PolySi) gate connected to the word-line (WL) of the array, as well as from the source-drain structure connected to the bit-line.

An exemplary process for fabricating the structure of FIG. 24-25 comprises the following steps:

(a) Starting substrate: silicon-on-insulator (SOI) wafer;

(b) Thin down SOI film down to 50 nm by oxidation;

(c) Fin patterned by spacer lithography, T_{Si}=20 nm;

(d) 2 nm sacrificial oxide to improve the quality of the etched fin sidewalls;

(e) 5.0 nm thermal gate oxide, 810° C., 10% O₂ ambient;

(f) 150 nm LPCVD N+ poly gate, 615° C.;

(g) 150 nm LPCVD LTO (hard mask for gate), 450° C.;

(h) Gate patterned by DUV lithography, L_{g}=100 nm;

(i) Thermal oxidation (810° C. in 10% O₂ ambient) to simultaneously grow 3.0 nm thermal tunnel oxide around the fin sidewalls, and ˜5.0 nm control oxide grown around the gate sidewalls;

(j) 15 nm LPCVD nitride, 750° C.;

(k) Anisotropic dry etching to define gate-sidewall spacers;

(l) Source/drain doping & activation: P³¹ 40 keV, 1e16 cm⁻², 920° C., 30 s;

(m) Contact formation and metallization; and

(n) N₂/H₂ anneal at 400° C. for 30 min.

C. Four Bit-Per-Cell Operation

The identification of four storage bits per cell is described in reference to the general configurations shown in FIG. 4A-4B, and by utilizing a novel charge-detection read method.

1. Novel Method of Charge Detection:

In addition to the conventional charge detection method, a change in off-state current can also be used to selectively distinguish the uncharged state of any bit of the proposed structures (shown in FIG. 4A-4B), especially when using asymmetric gates since these enhance the GIDL effect. In the novel charge detection method, the change in off-state current arises from the change in the transverse electric field due to the charge stored at the bit closest to the drain (D) electrode and the gate that is turned on.

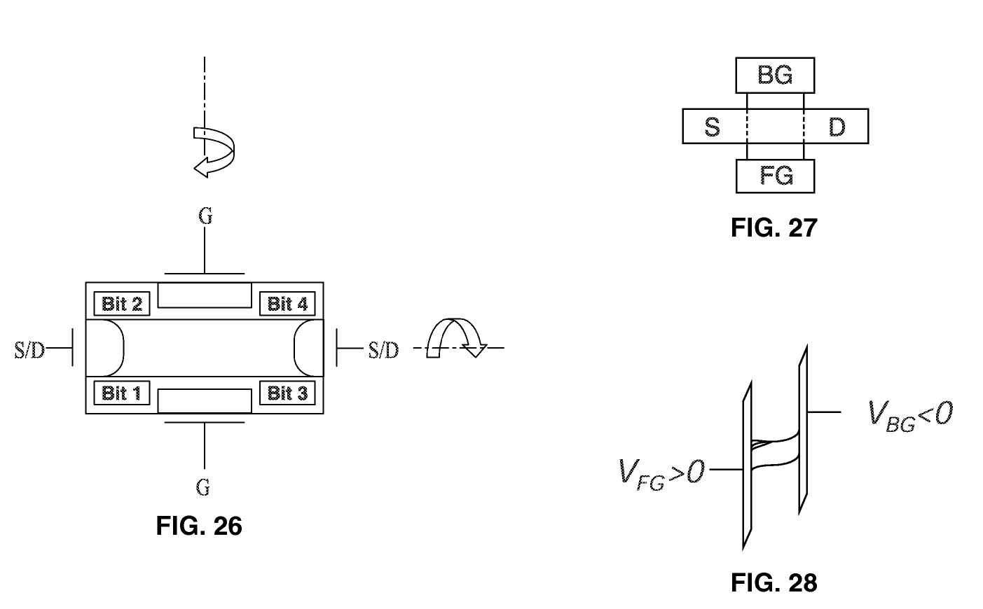

2. Symmetry: As shown in FIG. 26, this embodiment of the invention has a structure that is symmetric with respect to the source (S) and drain (D) electrodes and both gates. Thus, bit 3 (bit 2) becomes bit 1 (bit 4) when the source (S) and drain (D) electrodes are interchanged. This feature allows identification of the symmetric bit once the original bit is determined.

3. Symmetric Gates: In this embodiment, symmetric gates are employed (e.g., n⁺ poly-Si for both front and back gates) to attain a fully symmetrical cell, as shown in FIG. 26.

4. Independent-Gate Biasing: In this embodiment, independent biasing of each gate, specifically front gate (FG) and back gate (BG), as seen in FIG. 27, can effectively modulate the threshold voltage (V_{T}) and subthreshold swing (S) for a dual-gate (DG) FET.

This feature can thus be used to “mask” the bit information stored at the opposing gate while bit information stored at the selected gate is determined. For instance, the bit information stored at the FG can be “masked” while reading the bit information stored in the BG by placing the channel next to the FG in accumulation mode and the channel next to the BG in inversion mode (e.g., by applying V_{FG}<0, V_{BG}>0). Note that asymmetric gates are not really required to distinguish the bits located at the FG or BG if independent-gate biasing is also used; however, asymmetric gates are still preferred as they generally enhance the GIDL effect.

All these features are utilized to properly identify the state of each bit in the cell. The state of each bit can be detected in the conventional manner by sensing the transistor current in the on-state, since the threshold voltage (V_{T}) of the cell will be affected by the presence of charge stored in the bit next to the source electrode. By biasing the unselected gate to a negative voltage, the bits next to it can be effectively masked while the bits next to the selected gate are read. For instance, the state of the bit close to the source electrode and beside the front gate (e.g., bit 1) can be determined (with the conventional read method) by application of a moderate V_{ds} (e.g., 1.0V), with V_{FG}=0.5V, V_{BG}=−2.0V. With these settings, significant I_{DS} current will flow through the cell if there is NO charge stored at bit 1 (since the cell's V_{T} is only affected by the presence of charge on the bit closest to both the source electrode and the front-gate in this case) regardless of the state of the other bits. To distinguish the bit information stored at another bit, the roles of the source and drain electrodes (and both gates) are simply interchanged.

The same principles can be utilized with the novel charge detection method described herein. For instance, the state of the bit next to the drain electrode and beside the back gate (e.g., bit 4) is determined by application of a moderate V_{ds} (e.g., 1.5V), while the FG is biased to a negative voltage (e.g., about −1V) with V_{BG}=−2.0V. With these settings, significant I_{DS} current, such as principally GIDL current, will flow through the selected cell if there is charge stored at that site, regardless of the state of the other bits. As before, the state of a symmetric bit is similarly determined upon exchange of the roles of source and drain as well as both gates.

5. NOR-Type 4-Bit DG FET Array Architecture:

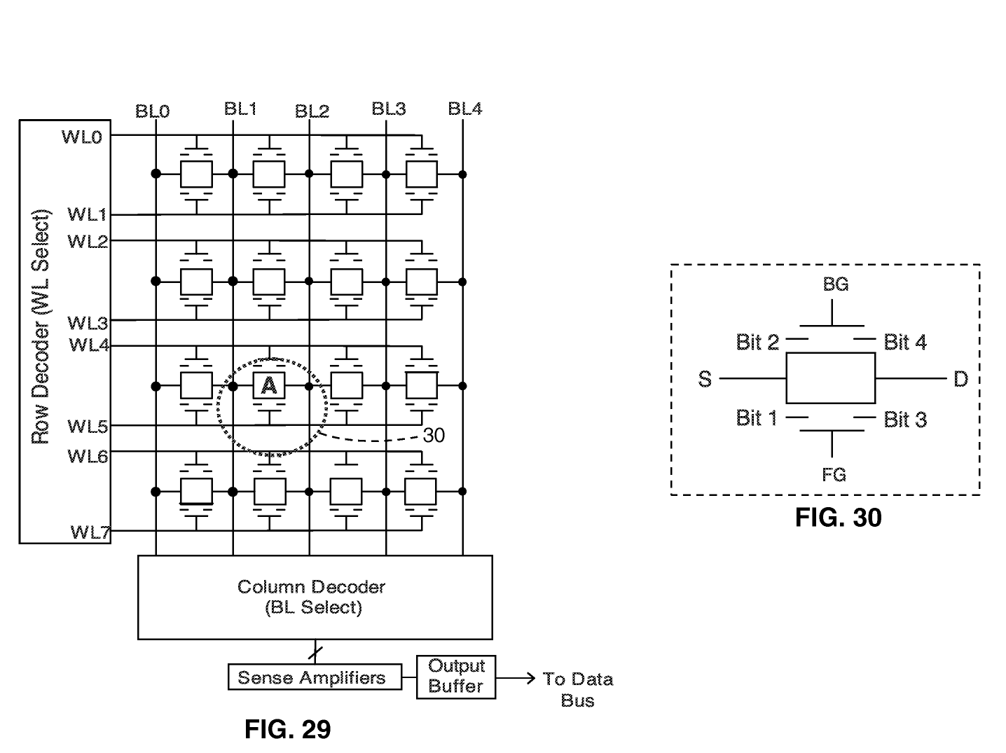

FIG. 29-30 show a circuit diagram of a NOR-type array architecture that utilizes a double-gated NVM FET (e.g., cell shown in FIG. 4A-4B) as its unit cell, along with the operating conditions (Table 7) required to read each bit of cell ‘A’ in the array.

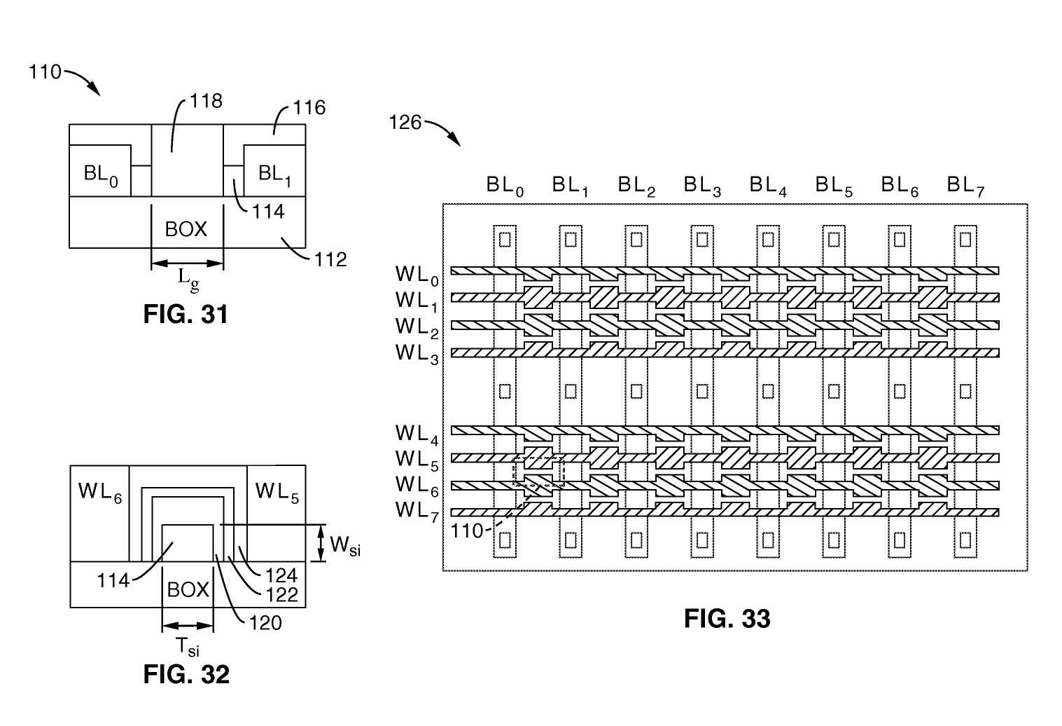

FIG. 31-33 shows a basic layout (not to scale) of an NVM cell embodiment 110 and NOR-type array architecture 126 according to the present invention. In FIG. 31 the bit-lines, BL₀, BL₁ are depicted on the BOX 112, and between which are disposed fin 114 and a portion 118 of WL₆. In FIG. 32 the write lines WL₆ and WL₅ can be seen with the structure surrounding fin 114 and comprising a silicon dioxide (SiO₂) gate oxide layer 120, a silicon nitride (Si₃N₄) charge-trapping region 122, and a SiO₂ control oxide layer 124.

As shown in FIG. 31-32, one embodiment of this architecture uses SOI technology, although this is not required, and the unit cell is the DG SONOS NVM cell structure according to the present invention (although the architecture applies to structures shown in FIG. 4A-4B). This architecture utilizes symmetry to treat each bit-line as a source or drain electrode as necessary and thus attain multiple bits of storage in every cell. This symmetry has been successfully used in the planar virtual ground NROM architecture to attain two bits per cell. The symmetry of the cells in this case with respect to both gates is also utilized to attain four bits, instead of two bits, of storage per every unit cell.

6. NAND-Type 4-Bit DG FET Array Architecture:

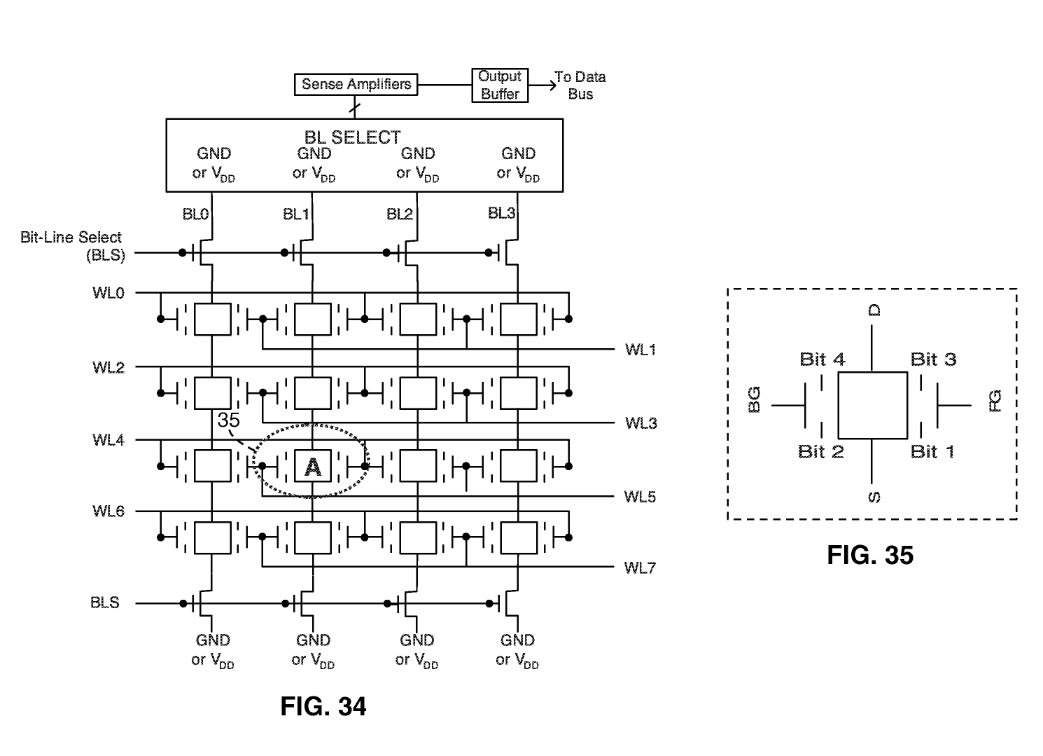

FIG. 34-35 illustrate a circuit diagram of a NAND-type array architecture that utilizes a double-gated NVM FET, such as the FinFET SONOS NVM cell, as its unit cell. In this architecture, cells belonging to the same bit-line are connected in series between two bit-line select (BLS) transistors, which are each configured to pass a high voltage (e.g., V_{DD}) as well as a low voltage (e.g., GND) to allow for forward-read as well as reverse-read operations of each cell. This architecture can also be implemented in practice with SOI technology, where the unit cell is either of the cell structures shown in FIG. 4A-4B, or similar structures.

7. Conventional Read Method w/NOR-Type Architecture:

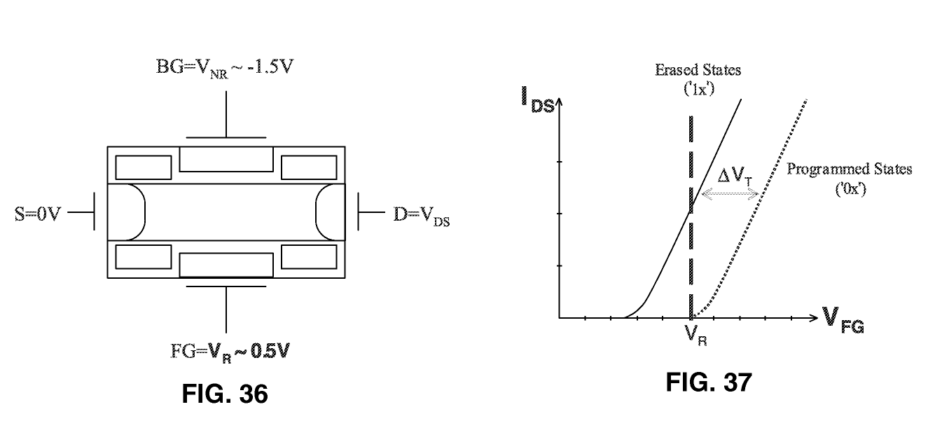

The state of bit 1 (16 possibilities: ‘1xyz’ or ‘0xyz’, where ‘xyz’ represents any one of the eight potential binary states of the remaining 3 bits) of the selected cell (cell A) in FIG. 29-30 is determined through application of a moderate V_{ds} (e.g., 1.5V), with V_{FG}=0.5V, V_{BG}=−2.0V. With these settings, significant I_{DS} current will flow through the selected cell if there is no charge stored at that site, as represented in FIG. 36-37.

A sense amplifier then detects the current, and the bit information stored in that site is thus identified. In this embodiment, all unselected cells belonging to the same column are turned off completely (in order to minimize any leakage current from these cells) through application of a small negative bias (e.g., close to 0V) on their gates. A low drain-to-source voltage V^{DS} (˜0V) is applied to all cells within the same row as the selected cell to minimize leakage current arising from these cells. A sense amplifier then detects the current, and the bit information stored in that site is thus identified.

To read any of the other bits within cell A, the roles of the source and drain electrodes, and both gates, are interchanged as necessary. Table 7 lists the operating voltages required to read each bit of cell A within this array architecture, such as utilizing a conventional read method.

8. Conventional Read Method w/NAND-Type Architecture:

The state of bit 1 (16 possibilities: ‘1xyz’ or ‘0xyz’, where ‘xyz’ represents any one of the eight potential binary states of the remaining 3 bits) of the selected cell (cell A) in FIG. 34-35 is determined through application of a moderate V_{ds} (e.g., V_{DD}˜1.5V), with V_{FG}=0.5V, V_{BG}=−2.0V. With these settings, significant I_{DS} current, as seen in the graph of FIG. 37, will flow through the selected cell if there is no charge stored at that site as shown in FIG. 36. In this embodiment, all unselected cells belonging to the same column are turned on completely, thus acting as pass transistors regardless of the bit information stored in them, through application of a large positive bias (“V_{P}”) on their gates. The value of V_{P}, however, should not be so large as to foster potential read disturbances. The equivalent circuit shown in FIG. 21 results from these bias conditions. To read any of the other bits within cell A, the roles of the source and drain electrodes, and both gates, are interchanged as necessary. Table 8 lists the operating voltages required to read each bit of cell A within this array architecture utilizing the conventional read method.

9. Program: Each bit can be independently programmed via hot electron injection (HEI) in a manner similar to that used for the sidewall nonvolatile memory device reported in M. Fukuda, T. Nakanishi and Y. Nara, “New Nonvolatile Memory with Charge-Trapping Sidewall,” IEEE EDL, Vol. 24, No. 8, p. 490 (2003), incorporated herein by reference in its entirety. To write a bit, the appropriate gate and drain electrodes, nearest to the bit, are each biased to a high voltage (≦5V), while the source is grounded and the opposite gate is biased to a high negative voltage.

10. Erase: Each bit can be independently erased via hot hole injection (HHI). To erase either of the bits next to the drain electrode, the drain is biased to a high voltage and the source is grounded to generate holes next to the drain electrode either utilizing impact ionization or band-to-band tunneling (BTBT), or similar mechanisms. To direct the generated holes towards the charge-trapping region, the gate electrode (nearest to the bit) is biased to a large negative voltage and the opposite gate is grounded. As shown before, hot holes can be readily generated to erase a FinFET SONOS device without a body contact.

D. Four Bit-Per-Cell Process Flow

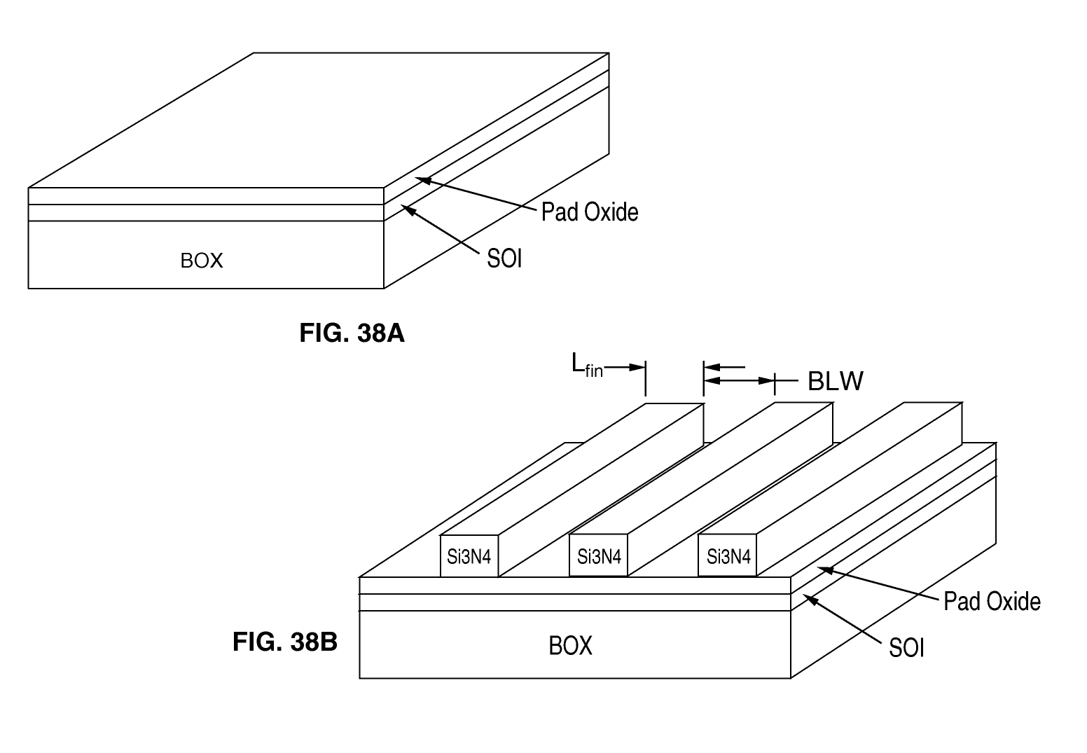

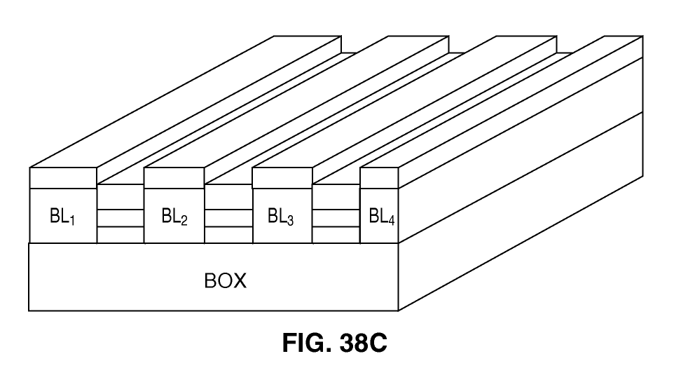

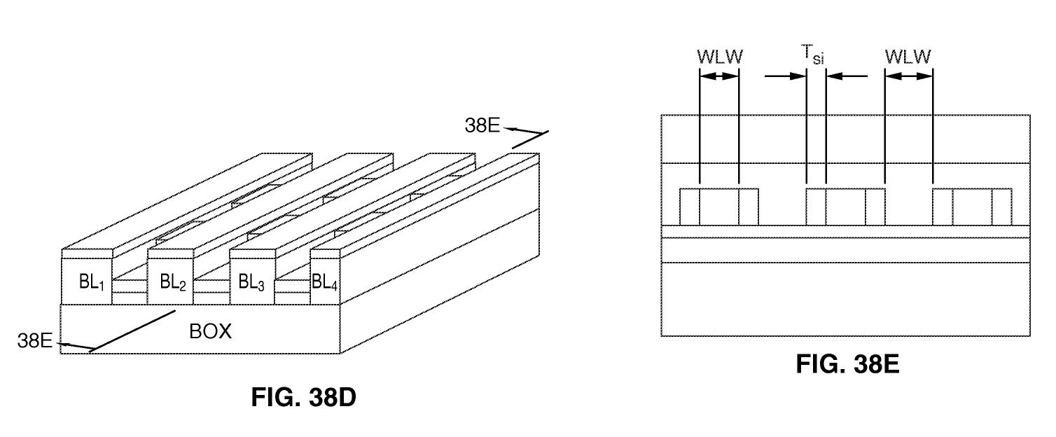

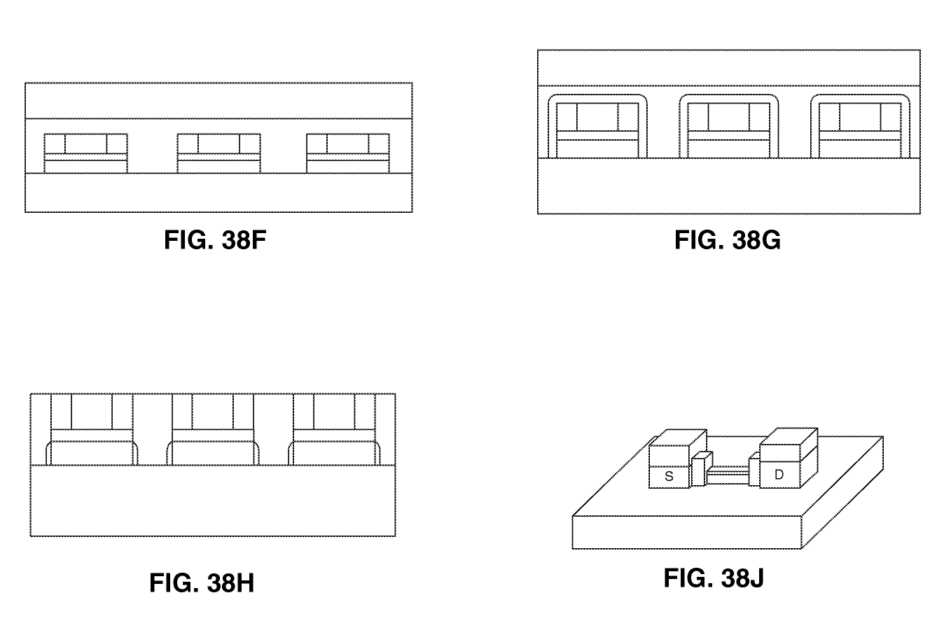

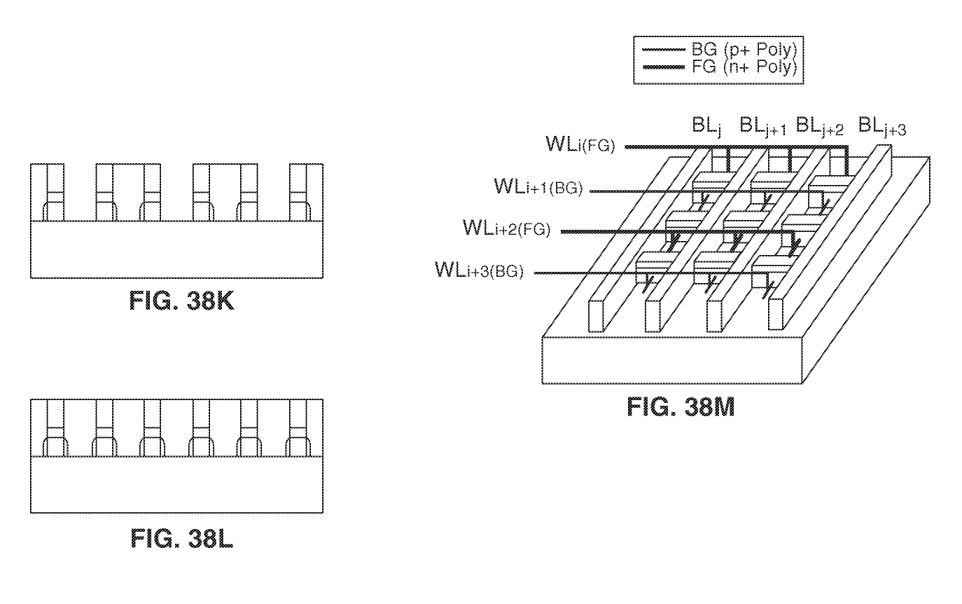

The structures shown in FIG. 4A-4B can be attained either with SOI technology or with planar technology. An exemplary process flow for the architecture (that uses SOI technology) is given in FIG. 38A-38M and comprises the following steps:

1. Bit Line Definition (FIG. 38A-38C):

As shown in the figure, the height of the bit lines (BLs) must be larger than the height of the Si₃N₄-PadOX—SOI stack. This is needed so that the silicon nitride (Si₃N₄) spacer (in FIG. 38G-38J) only grows next to the BLs and not in the middle of the fin, as shown in FIG. 38J. In moving from FIG. 38A to FIG. 38B, Si₃N₄ is deposited followed by lithography and etching steps. Then to arrive at FIG. 38C source-drain implantation is performed, oxide is removed, in-situ N+ PolySi is deposited and etched, and thermal oxidation is performed on the structure. It should be noted that BLW[=]Bit Line Width; and L_{fin}[=]L_{gate}+2×L_{spacer}.

2. Island Formation (FIG. 38D-38E):

This step defines the layout of sacrificial layers (Si₃N₄, Phosphosilicate glass “PSG”) that serves to protect one of the gates (in this case, the BG) and the fin structures while the other gate (including its spacers) is defined. In moving from FIG. 38C to 38D lithography and etching are performed followed by thermal oxidation. Then to arrive at FIG. 38E, PSG a deposition operation is performed followed by lithography and etching of the PSG. It should be noted that WLW[=]Word Line Width.

3. Front Gate (Spacer, Gate) Definition (FIG. 38F-38J):

This is a gate-last process step in which the spacer is defined first (including the ONO stack if defining the structure shown in FIG. 4B; otherwise, the spacer is only Si₃N₄ and the ONO stack is then formed underneath the FG), followed by the FG gate-stack (SiO₂-n⁺ PolySi gate stack for the structure in FIG. 4B) definition. In moving from FIG. 38E to FIG. 38F, etching of pad OX, SOI, as well as SiO₂ growth and etching. Then Si₃N₄ is deposited and the spacer is dry etched to define the Si₃N₄ spacers shown in FIG. 38G. FIG. 38J shows a tri-dimensional (3D) view of the unit cell after completion of this step. It should be noted that the Si₃N₄ spacer is only placed at the edges of the fin and next to the source and drain portions of the structure. Then a thermal oxidation step is performed to define the gate oxide on the FG, in-situ n⁺ PolySi deposited and a Chemical-Mechanical Polishing (CMP) step is then performed to arrive at FIG. 38H.

4. BG (Spacer, Gate) Definition (FIG. 38K-38M):

Step 3 is repeated for the BG, after the sacrificial layer (Si₃N₄) is removed. In moving from FIG. 38H to FIG. 38K a wet etch of the Si₃N₄ is performed, followed by a dry etch of pad OX, SOI, and then SiO₂ is grown and etched. Then the back gate (BG) spacers and gate stacks are defined to arrive at FIG. 38L. A back end process is performed to form the write lines shown in FIG. 38M.

Simulation Results

1. Two Bit-Per-Cell SG FET:

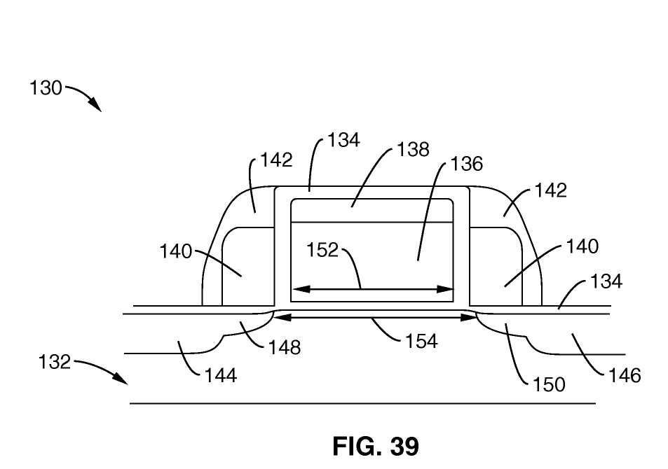

FIG. 39 is a Single-Gate (SG) n-channel FET structure embodiment 130, as previously shown in FIG. 3, shown here with each element detailed. A substrate 132, such as a conventional p-type silicon substrate, is shown with an oxide layer, or other insulator, on top, upon which a (n⁺ PolySi) gate 136, as an example, is formed with salicide layer 138 and surrounded by additional insulation 134. A charge-trapping region 140, comprising any material that can store charge, such as Si₃N₄, is shown proximal the gate and covered by another insulator layer 142 (e.g., Phosphosilicate glass “PSG”). It will be seen that the substrate is doped with n+ regions 144, 146 away from the channel, and n− regions 148, 150, beneath the trapping regions. In this structure the effective length of the gate 152 can be made to approximate the actual gate length 154.

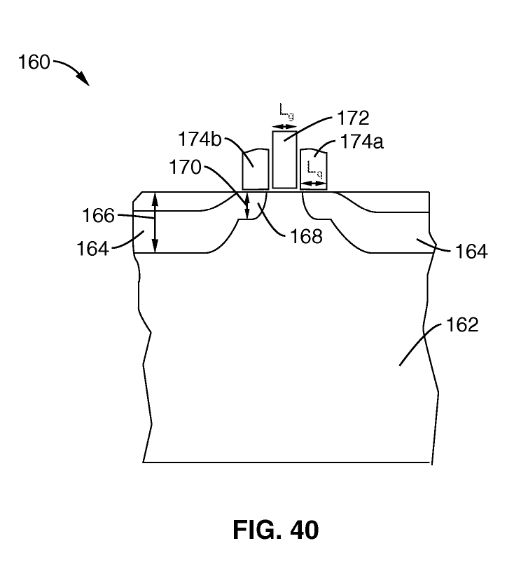

Simulation was performed according to the schematic of FIG. 40, which is a simplified version of FIG. 39, showing structure 160 with substrate 162, first doping (n+) 164 to a depth of 166, and second doping (n−) 168 to a depth 170. A gate region 172 is represented with width L_{g} and charge-trapping regions 174a, 174b were represented with width L_{q}. Simulation was performed using the 2D Taurus numerical device simulator. In these simulations, the design parameters shown in Table 10 were chosen. The device was simulated with cells utilizing either PolySi or silicon nitride (Si₃N₄) for the charge-trapping region 140, with parameter values shown in Table 10 for each material. Additionally, the areal density of traps at the bottom interface (nearest to the channel) of the trap film was set to a value of 1×10¹³ cm⁻². To attain a structure with an electrical channel length (L_{eff}) roughly equal to the cell's gate length (L_{g}), the source and drain junction edges were placed at the edges of the (n⁺ PolySi) gate electrode. To obtain the I_{ds}-V_{G} characteristics of all four possible states, the input voltage to the gate was swept from −2.5V to 2.5V while V_{ds} was maintained at a specific value (e.g., 1.5V).

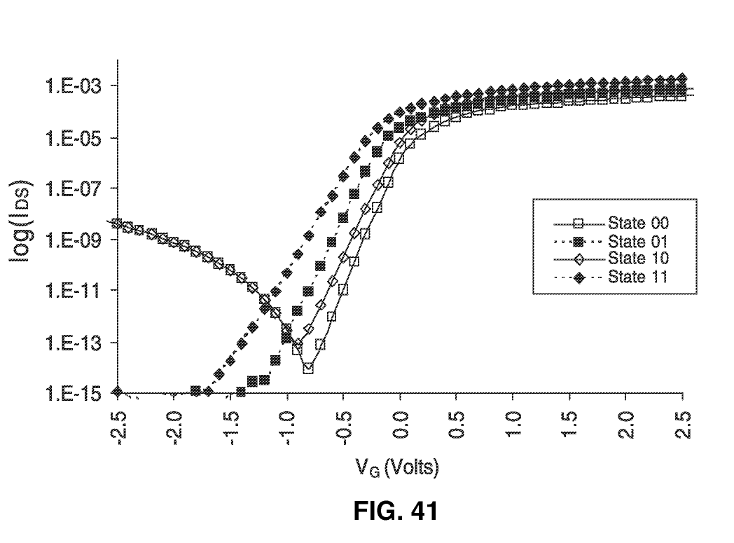

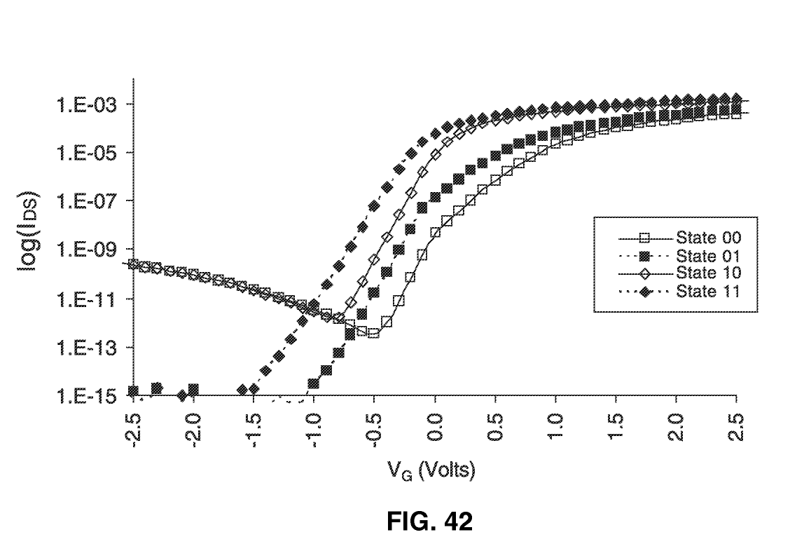

FIG. 41-42 depicts the log(I_{ds})-V_{G} characteristics for all four possible states when the cell uses PolySi (FIG. 41) or Si₃N₄ (FIG. 42) as the charge-trapping material. As shown, the four distinct binary states, specifically 00b, 01b, 10b, 11b, are clustered into two distinct groups of curves for V_{G}<0 corresponding to states with (00b, 10b) or without (01b, 11b) charge stored on the bit nearest to the drain electrode. This result is due to the change in GIDL current (ΔI_{GIDL}) when charge is stored at that site, as already mentioned. Additionally, no significant separation between the four distinct states is observed on all curves for V_{G}>0 corresponding to states with (00b, 01b) or without (10b, 11b) charge stored on the bit nearest to the source electrode. This is due to the fact that charge placed in the source electrode no longer affects the V_{T} of the cell in this gate-overlapped structure, wherein the source and drain junction edges actually overlap the charge-trapping sites.

As shown in these plots, the resulting change in I_{GIDL}, between the programmed and erased bit next to the drain electrode, at V_{G}˜−2.5 V is about six orders of magnitude (when using PolySi as the charge-trapping film) in I_{DS} for V^{DS}=1.5V. In addition, the resulting change in I_{GIDL}, between the programmed and erased bit next to the drain electrode, at V_{G}˜−2.5 V is about five orders of magnitude (when using Si₃N₄ as the charge-trapping film) in I_{DS} for V^{DS}=2.5V. Accordingly, these simulations show that the expected change in I_{GIDL} is indeed significant and thereby readily detected.

In both cases above, the separation in GIDL current (ΔI_{GIDL}) is sufficiently large to allow proper identification of each bit of the cell (due to the symmetry of the structure).

2. Two-Bit-Per-Cell DG FET:

The DG n-channel FET structure shown in FIG. 4B was simulated using the 2D Taurus numerical device simulator. In these simulations, the design parameters shown in Table 9 were chosen. PolySi was the material of choice for the charge-trapping region. Additionally, the areal density of traps at the bottom interface (nearest to the channel) of the trap film was set to a value of 5×10¹² cm⁻². To maximize the separation between programmed and erased states, the source and drain junction edges were placed at the midpoints of the length of the charge-trapping film. This setup should both maximize the change in GIDL current, due to charge stored next to the drain electrode, and the change in V_{T} due to charge stored next to the source electrode. To obtain the I_{ds}-V_{G} characteristics of all four possible states, the input voltage to both gates are swept together from −2V to 2.5V while V_{ds} is maintained at a specific value (e.g., 1.0V).

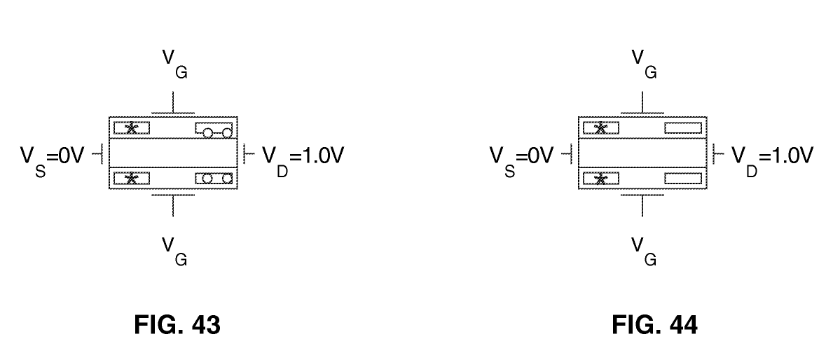

FIG. 43-44 illustrates the four distinct binary states (00b, 01b, 10b, 11b) which are clustered into two distinct groups of curves for V_{G}<0 corresponding to states with (00b, 10b) or without (01b, 11b) charge stored on the bit nearest to the drain electrode.

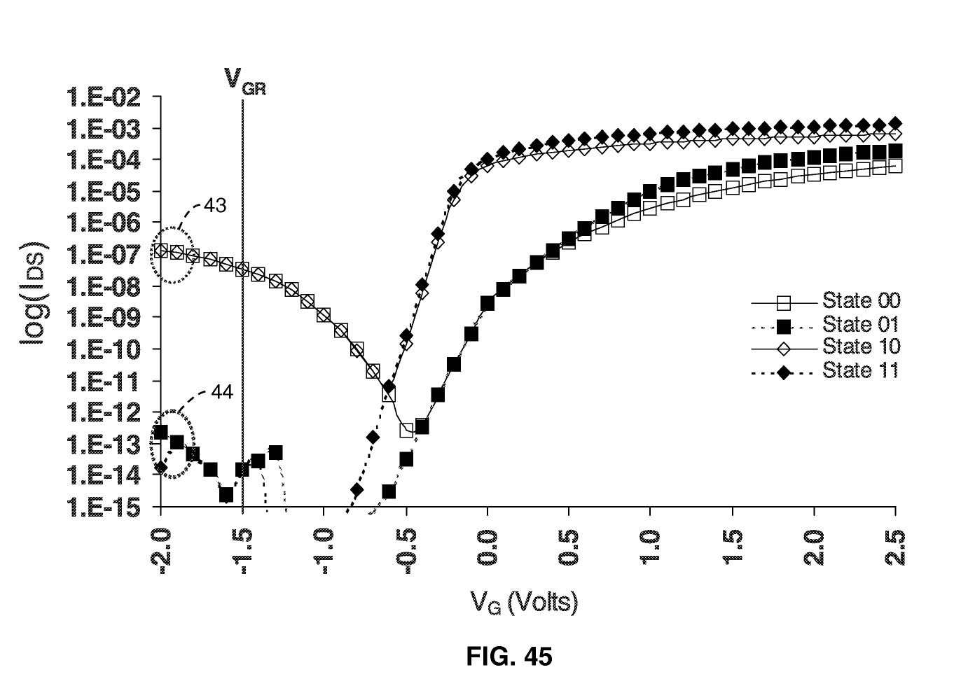

FIG. 45 depicts the log(I_{ds})-V_{G} characteristics for V_{ds}=1.0 V of FIG. 4B with the four possible states shown in FIG. 43-44. This result is due to the change in GIDL current (ΔI_{GIDL}) when charge is stored at that site, as already mentioned. Additionally, the four distinct states are also clustered into two distinct groups of curves for V_{G}>0 corresponding to states with (00b, 01b) or without (10b, 11b) charge stored on the bit nearest to the source electrode. This observation is the familiar change in V_{T} (ΔV_{T}) normally observed in NVM cells when charge is stored on the bit next to the source electrode. As shown in these plots, the resulting change in I_{GIDL} (between the programmed and erased bit next to the drain electrode) at V_{G}˜−1.5 V is about six orders of magnitude in I_{DS} for V^{DS}=1.0V. In addition, the resulting change in I_{ds} (between the programmed and erased bit next to the source electrode) at V_{G}˜0V is about four orders of magnitude. Accordingly, these simulations show that the expected change in I_{GIDL} is more significant and therefore easier to detect. It should be appreciated that this separation in the response is sufficient to allow proper identification of each group and thus each bit of the cell.

3. Four Bit-Per-Cell DG FET:

The DG n-channel FET structure from FIG. 4B was simulated using the 2D Taurus numerical device simulator. In these simulations, the design parameters shown in Table 11 were chosen. PolySi was the material of choice for the charge-trapping region. Additionally, the areal density of traps at the bottom interface (nearest to the channel) of the trap film was set to a maximum value of 5×10¹²cm⁻², which is a value used by other investigators. To maximize the separation between programmed and erased states, the source and drain junction edges must fall near the length of the charge-trapping film. This setup should both maximize the change in GIDL current (if any, due to charge stored on the bits next to the drain electrode) and the change in V_{T} due to charge stored on the bit(s) next to the source electrode. To obtain the I_{ds}-V_{FG} characteristics of all 16 possible states, the voltage input to the front gate (FG) is swept from −2V to 2.5V while both V_{ds} and V_{BG} are maintained at a specific value.

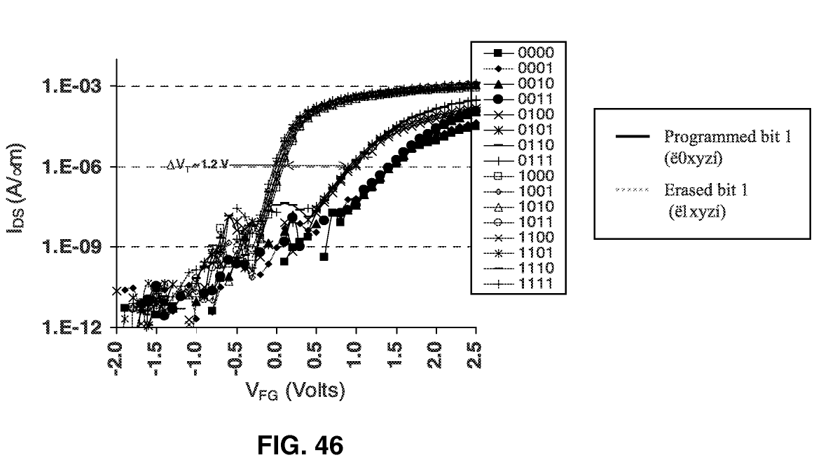

FIG. 46 shows the simulated drain current in response to selected gate voltage (I_{D}-V_{FG}) curves with the unselected gate (the BG in this case) biased at −1.5V and drain-to-source bias V^{DS}=1.5V. The curves are clearly seen to be clustered into two groups (‘0xyz’, ‘1xyz’), separated by a shift in threshold voltage (ΔV_{T}) greater than 1V according to the charge stored at the selected bit near to the source (e.g., Bit 1). This V_{T} separation is sufficiently large so as to allow easy detection of charge stored at the selected bit (e.g., by applying V_{FG}=0.5V and sensing the transistor current). Due to the symmetry of the cell structure, the state of each bit can be determined by a sequence of four read operations. For example, to read the bit next to the source electrode and beside the back gate (e.g., Bit 2), the back gate is biased to a positive voltage (V_{BG}˜0.5V) while the front gate is biased to a negative voltage (V_{FG}˜−1.5V) with a moderate drain-to-source bias applied (V^{DS}˜1.5V). To read the complementary bits (e.g., Bits 3 and 4), the roles of the source and drain electrodes are interchanged (e.g., the transistor is operated in reverse mode).

4. Four Bit-Per-Cell ADG FET:

The ADG n-channel FET structures shown in FIGS. 4A, 4B were simulated using the 2D Taurus numerical device simulator, utilizing design parameters shown in Table 12. PolySi was the material of choice for the charge-trapping region. Additionally, the areal density of traps at the bottom interface (nearest to the channel) of the trap film was set to a maximum value of 5×10¹² cm⁻², a value used by other investigators. To maximize the separation between programmed and erased states, the source and drain junction edges were placed at the midpoints of the length of the charge-trapping film. This setup should both maximize the change in GIDL current, due to charge stored next to the drain electrode, and the change in V_{T} due to charge stored next to the source electrode. To obtain the I_{ds}-V_{BG} characteristics of all sixteen possible states, the input voltage to the backgate (BG) was swept from −2V to 2.5V while both V_{ds} and V_{FG} were maintained at a specific value.

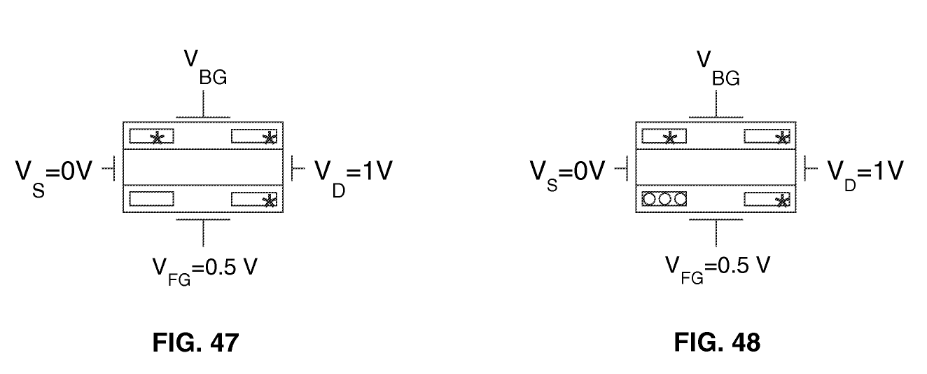

FIG. 47-48 illustrate the states 1xyz and 0xyz respectively for the simulation of charge storage at Bit 1, which is closest to the source and the front gate.

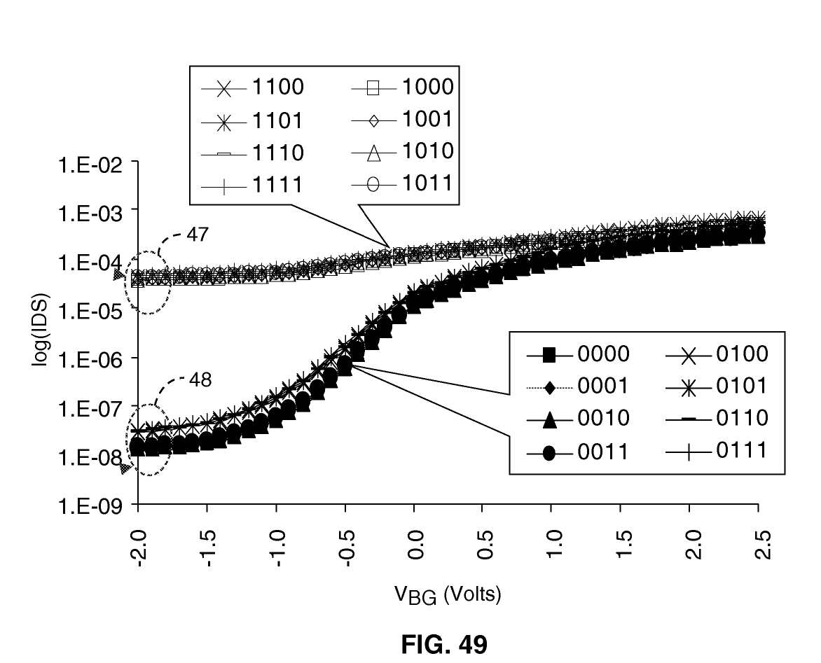

FIG. 49 illustrates log(I_{ds})-V_{BG} characteristics for V_{FG}=0.5V, −1.0 V for all sixteen possible states. As shown, the sixteen distinct states are clustered into two distinct groups of curves for V_{BG}<0 corresponding to states with (0xyz) or without (1xyz) charge stored on bit 1. This result is due to the change in off-state current when charge is stored at that site, as already mentioned.

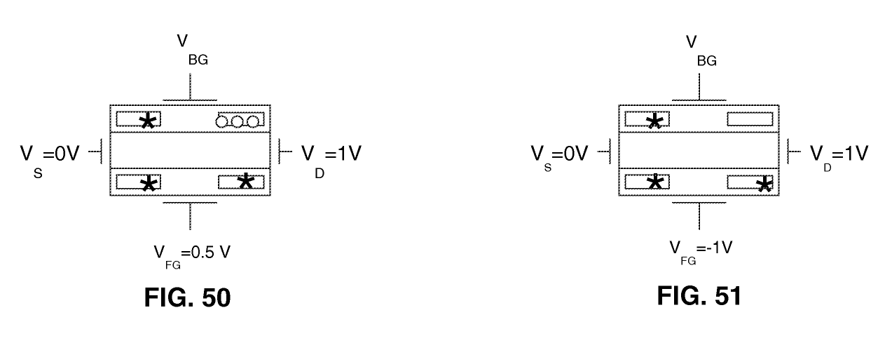

FIG. 50-51 illustrate the states xyz0and xyz1 respectively for the simulation of charge storage at Bit 4, which is closest to the drain and the back gate.

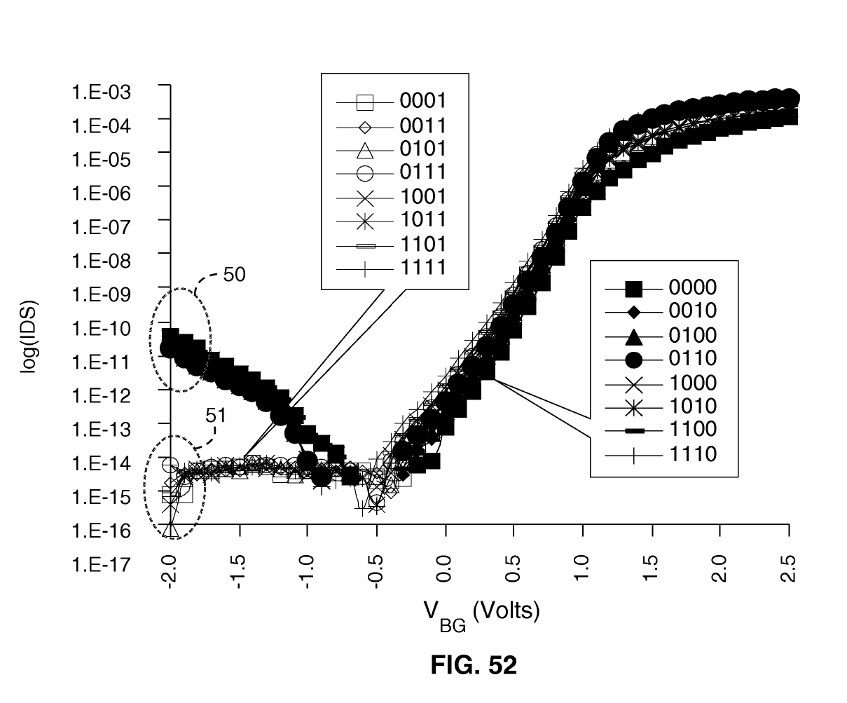

FIG. 52 illustrates log(I_{ds})-V_{BG} characteristics for the back gate with all sixteen states represented. As shown, the sixteen distinct states are clustered into two distinct groups of curves for V_{BG}<0 corresponding to states with (xyz0) or without (xyz1) charge stored on bit 4. This result is due to the change in off-state current when charge is stored at that site, as already mentioned.

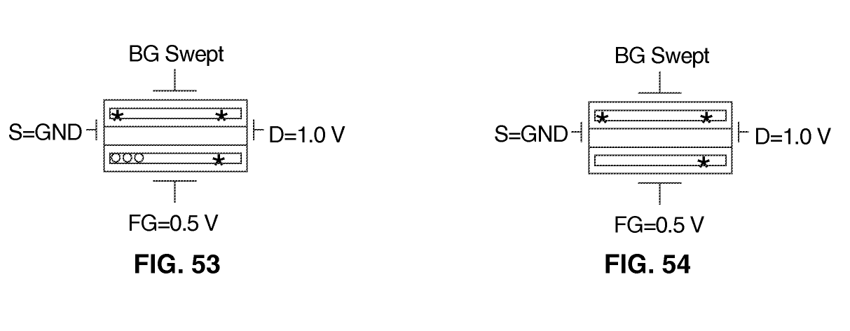

FIG. 53-54 illustrates the charged (0xyz) and uncharged (1xyz) states, respectively, for bit 1 of a SONOS ADG FET device simulation.

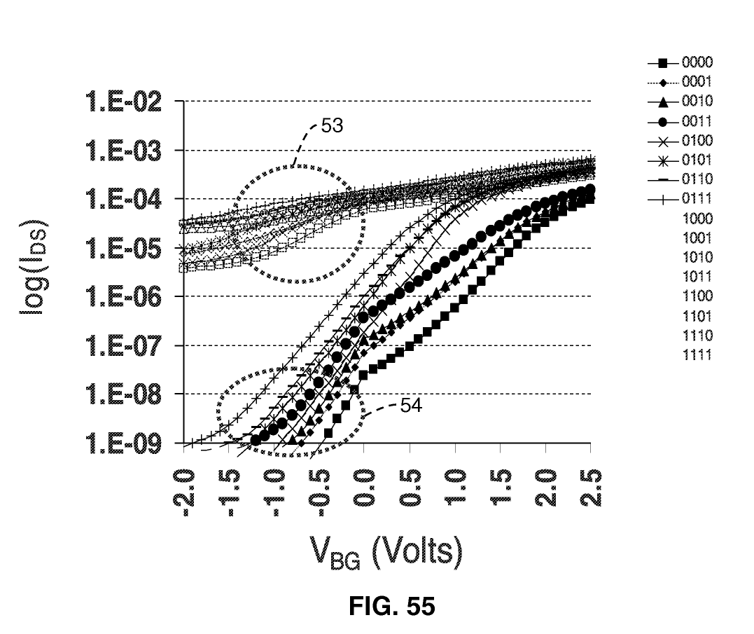

FIG. 55 illustrates a graph log(I_{ds}) in response to V_{BG} for the states of bit 1 in the SONOS device represented in FIG. 53-54. As shown, the sixteen distinct states are clustered into two distinct groups of curves for V_{BG}<0 corresponding to states with (0xyz) or without (1xyz) charge stored on bit 1. This result is due to the change in off-state current when charge is stored at that site, as already mentioned.

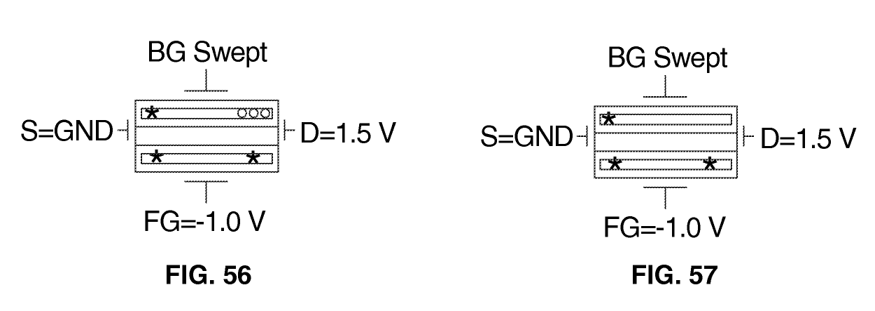

FIG. 56-57 illustrates the charged (xyz0) and uncharged (xyz1) states, respectively, for bit 4 of a SONOS ADG FET device simulation.

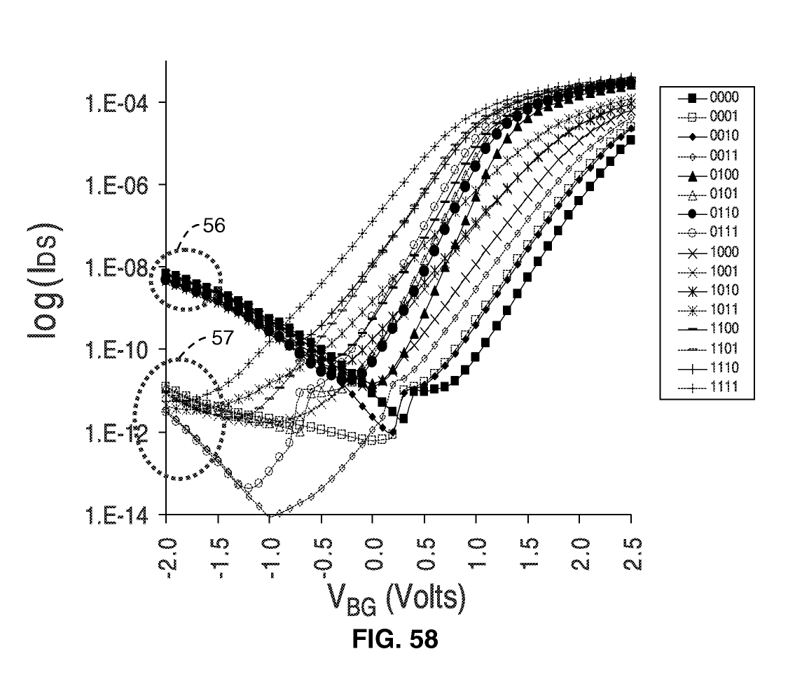

FIG. 58 illustrates a graph log(I_{ds}) in response to V_{BG} for the states of bit 4 in the SONOS device represented in FIG. 56-57. As shown in FIG. 55 and FIG. 58, the SONOS-like device shows more intra-group variability, due to a higher sensitivity to charge fluctuations because the charge-trapping region is located underneath the gate electrode. In the latter case (V_{FG}=−1.0V), the sixteen distinct states are also clustered into two distinct groups of curves for V_{BG}<0 corresponding to states with (xyz0) or without (xyz1) charge stored on bit 4. This result is due to the change in GIDL current when charge is stored at that site. As before, the SONOS-like device shows enhanced intra-group variability.

As shown in these plots, the resulting change in off-state current (between the programmed and erased bit) at V_{G}˜−2.0 V is about three orders of magnitude in each case. Thus, these simulations show that the expected change in off-state current is indeed significant and thus easy to detect. This separation is sufficiently large to provide proper identification of each group and thus each bit of the cell (due to symmetry).

From the Taurus simulations performed, the DG FET (when used either as a two bit-per-cell or a four bit-per-cell structure) shows significant separation between programmed, erased states when using a change in off-state current (or on-state current, with the conventional read method) to identify the difference. This difference in current (at least three orders of magnitude) is sufficient to allow proper identification of the state of the bit, while the operating voltages required to obtain the information stored in the cell are sufficiently low so as to minimize read disturbances. Because of the symmetry of the cell and the (NOR- and NAND-type) “Virtual Ground in SOI” architectures of the present invention, a maximum of four bits of every cell can be properly distinguished by either the conventional or the novel read methods. Thus, the inventive structure (in either mode of operation two bits or four bits-per-cell), method of charge detection and architectures (either alone or in conjunction) offer significant advantages over conventional NVM technologies.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art. In the appended claims, reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Operating Voltage Conditions on Selected Bit using the Conventional
Methods on a NOR-type Virtual-Ground Architecture

| | WL₁ | other WLs | BL₀ | BL₁ | BL₂ | BL₃ | BL₄ |
|---|---|---|---|---|---|---|---|
| Read | ˜0.5 | 0 V | 0 V | 0 V | 1.5 V | 1.5 V | 1.5 V |
| Program | ˜6 V | 0 V | 6.5 V | 6.5 V | 0 V | 0 V | 0 V |
| Erase | −6 V | 0 V | 6.5 V | 6.5 V | 0 V | 0 V | 0 V |

TABLE 2
Operating Voltage Conditions on Selected Bits using Conventional
Read Method on NOR-type Architecture

| Operation on | | | | | | | |
|---|---|---|---|---|---|---|---|
| BIT 2 | | other | | | | | |
| Cell ‘A’ | WL₁ | WLs | BL₀ | BL₁ | BL₂ | BL₃ | BL₄ |
| Read | V_{read} | V_{P} | 1.5 V | 1.5 V | 0 V | 0 V | open |
| (ΔV_{T}) | (>0 V) | | | | | | |
| Program | 6 V | 0 V | 0 V | 0 V | 6.5 V | 6.5 V | 6.5 V |
| (HEI) | | | | | | | |
| Erase | −6 V | 0 V | 0 V | 0 V | 6.5 V | 6.5 V | 6.5 V |
| (HHI) | | | | | | | |

TABLE 3
Operating Voltage Conditions on Selected Bits using Novel
Read Method on NOR-type Architecture

| Operation on BIT 2 | | other | | | | | |
|---|---|---|---|---|---|---|---|
| Cell ‘A’ | WL₁ | WLs | BL₀ | BL₁ | BL₂ | BL₃ | BL₄ |
| Read (ΔV_{T}) | V_{read} | Vₚ | 0 V | 0 V | 1.5 V | 1.5 V | 1.5 V |
| | (<0 V) | | | | | | |
| Program (HEI) | 6 V | 0 V | 0 V | 0 V | 6.5 V | 6.5 V | 6.5 V |
| Erase (HHI) | −6 V | 0 V | 0 V | 0 V | 6.5 V | 6.5 V | 6.5 V |

TABLE 4
Operating Voltage Conditions on Selected Bits using Conventional
Read Method on NAND-type Architecture

| Operation on BIT 2 | | other | BL₃ | BL₃ | other |
|---|---|---|---|---|---|
| Cell ‘A’ | WL₁ | WLs | (top) | (bottom) | BLs |
| Read (ΔV_{T}) | V_{read} | V_{P} | GND | V_{DD} | open |
| | (−0.5 V) | (˜2.5 V) | | (˜1.5 V) | |
| Program (HEI) | ˜6 V | ˜2 V | ˜6.5 V | GND | 6.5 V |
| Erase (FN Tunn) | −9 V | 0 V | 0 V | 0 V | 6.5 V |

TABLE 5
Operating Voltage Conditions on Selected Bits using Novel
Read Method on NAND-type Architecture

| Operation on BIT | | other | BL₃ | BL₃ | other |
|---|---|---|---|---|---|
| 2 Cell ‘A’ | WL₁ | WLs | (top) | (bottom) | BLs |
| Read (ΔV_{T}) | V_{read} | V_{P} | V_{DD} | GND | open |
| | (˜−1.5 V) | (˜2.5 V) | (˜1.5 V) | | |
| Program (HEI) | ˜6 V | ˜2 V | ˜6.5 V | GND | open |
| Erase (FN Tunn) | −9 V | 0 V | 0 V | 0 V | open |

TABLE 6
Operating Voltage Conditions on Selected Bits using Combined
Read Method on NAND-type Architecture

| Operation on | | | | | |
|---|---|---|---|---|---|
| BIT 1, | | other | BL₃ | BL₃ | other |
| BIT 2 of Cell ‘A’ | WL₁ | WLs | (top) | (bottom) | BLs |
| Read bit 1 | V_{read, 1} | V_{P} | V_{DD} | GND | open |
| (ΔV_{T}) | (˜0.5 V) | (˜2.5 V) | (˜1.5 V) | | |
| Read bit 2 | V_{read, 2} | V_{P} | V_{DD} | GND | open |
| (ΔI_{GIDL}) | (˜−1.5 V) | (˜2.5 V) | (˜1.5 V) | | |

TABLE 7
Operating Voltages Required to Read Each Bit of cell ‘A’ using
the Conventional Method on a NOR-type Architecture

| | V_{WL4} | V_{WL5} | other WLs | V_{BL0} | V_{BL1} | V_{BL2} | V_{BL3} | V_{BL4} |
|---|---|---|---|---|---|---|---|---|
| Bit 1 | −1.5 V | ˜0.5 V | 0 V | 0 V | 0 V | 1.5 V | 1.5 V | 1.5 V |
| Bit 2 | ˜0.5 V | −1.5 V | 0 V | 0 V | 0 V | 1.5 V | 1.5 V | 1.5 V |
| Bit 3 | −1.5 V | ˜0.5 V | 0 V | 1.5 V | 1.5 V | 0 V | 0 V | 0 V |
| Bit 4 | ˜0.5 V | −1.5 V | 0 V | 1.5 V | 1.5 V | 0 V | 0 V | 0 V |

TABLE 8
Operating Voltages Required to Read Each Bit of cell ‘A’ using
the Conventional Method on a NAND-type Architecture

| | V_{WL4} | V_{WL5} | other WLs | BLS | V_{BL1} (top) | V_{BL1} (bottom) |
|---|---|---|---|---|---|---|
| Bit 1 | 0.5 V | −1.5 V | 2.5 V | V_{DD} | V_{DD} | GND |
| Bit 2 | −1.5 V | 0.5 V | 2.5 V | V_{DD} | V_{DD} | GND |
| Bit 3 | 0.5 V | −1.5 V | 2.5 V | V_{DD} | GND | V_{DD} |
| Bit 4 | −1.5 V | 0.5 V | 2.5 V | V_{DD} | GND | V_{DD} |

TABLE 9
Parameter Settings for Taurus Simulations (2 bit/cell DG FET)

| Parameter | Size | |
|---|---|---|
| Gate Oxide, Tₒₓ | 6 | nm |
| Tunnel Oxide, Tₜₒₓ | 3 | nm |
| Gate Length, L_{g} | 70 | nm |
| Trap-region Length, Lₜᵣₐₚ | 13 | nm |
| Fin(body) thickness, Tₛᵢ | 12 | nm |
| Trap (PolySi) thickness, Tₜᵣₐₚ | 15.0 | nm |
| Control Oxide, CTₒₓ | 12.0 | nm |
| Q_{ox,max} | −5e12 | #/cm² |
| φ_{G} (n PolySi, both gates) | 4.17 | eV |
| Bulk (constant) doping for fin | 1e13 | #/cm³ |
| Peak doping for doped PolySI Gate | 1e20 | #/cm³ |
| Peak doping for S/D | 2e20 | #/cm³ |

TABLE 10
Parameter Settings for Taurus Simulations (Two bit SG FET)

| Parameter | (a) Cell 1 | | (b) Cell 2 | |
|---|---|---|---|---|
| Charge-trapping Material | PolySi | | Si₃N₄ | |
| Gate Oxide, Tₒₓ | 6 | nm | 6 | nm |
| Tunnel Oxide, Tₜₒₓ | 3 | nm | 3 | nm |
| Control Oxide, CTₒₓ | 5 | nm | 5 | nm |
| Gate Length, L_{g} | 45 | nm | 45 | nm |
| Trap-region Length, L_{Q} | 30 | nm | 30 | nm |
| S/D Doping (n⁺ region) | 2e20 | #/cm² | 2e20 | #/cm² |
| S/D Doping (n⁻ region) | 1e19 | #/cm² | 5e18 | #/cm² |
| Q_{ox,max} | −5e12 | #/cm² | −5e12 | #/cm² |
| φ_{FG} (n+ PolySi) | 4.17 | eV | 4.17 | eV |
| Bulk (constant) doping for fin | 6e17 | #/cm³ | 6e17 | #/cm³ |
| Applied V_{DS} voltage | 1.5 | V | 2.5 | V |

TABLE 11
Parameter Settings for Taurus Simulations (2 bit/cell DG FET)

| Parameter | Size | |
|---|---|---|
| Gate Oxide, Tₒₓ | 6 | nm |
| Tunnel Oxide, Tₜₒₓ | 3 | nm |
| Gate Length, L_{g} | 70 | nm |
| Trap-region Length, Lₜᵣₐₚ | 20 | nm |
| Fin(body) thickness, Tₛᵢ | 40 | nm |
| Trap (PolySi) thickness, Tₜᵣₐₚ | 15.0 | nm |
| Control Oxide, CTₒₓ | 12.0 | nm |
| Q_{ox,max} | −5e12 | #/cm² |
| φ_{G} (n PolySi, both gates) | 4.17 | eV |
| Bulk (constant) doping for fin | 1e13 | #/cm³ |
| Peak doping for doped PolySI Gate | 1e20 | #/cm³ |
| Peak doping for S/D | 2e20 | #/cm³ |

TABLE 12
Parameter Settings for Taurus Simulations (2 bit DG FET)

| Parameter | (a) Cell 1 | | (b) Cell 2 | |
|---|---|---|---|---|
| Gate Oxide, Tₒₓ | 3 | nm | 6 | nm |
| Tunnel Oxide, Tₜₒₓ | n/a | | 3 | nm |
| Control Oxide, CTₜₒₓ | 12 | nm | 5 | nm |
| Gate Length, L_{g} | 70 | nm | 70 | nm |
| Trap-region Length, L_{Q} | 13 | nm | 70 | nm |
| Fin thickness, Tₛᵢ | 40 | nm | 40 | nm |
| Q_{ox,max} | −5e12 | #/cm² | −5e12 | #/cm² |
| φ_{FG} (n+ PolySi) | 4.17 | eV | 4.17 | eV |
| φ_{BG} (p+ PolySi) | 5.17 | eV | 5.17 | eV |
| Bulk (constant) doping for fin | 1e13 | #/cm³ | 1e13 | #/cm³ |

What is claimed is:

1. An apparatus, comprising:
a transistor structure;
said transistor structure having at least one gate electrode;
said transistor structure having at least one charge-trapping region configured to store a bit of information;
wherein off-state current is utilized to distinguish charge state of said bit in said transistor structure.

2. An apparatus as recited in claim 1:
wherein a bit state in the transistor structure is determined by off-state current; and
wherein a change in off-state current is utilized to determine a change in charge state of a bit in the charge-trapping region.

3. An apparatus as recited in claim 1, wherein a change in the off-state current arises from a change in transverse electric field due to stored charge.

4. An apparatus as recited in claim 1, wherein said transistor structure has one or more charge-trapping regions configured for storing 2 bits of information.

5. An apparatus as recited in claim 4, wherein said transistor structure comprises a single-gate transistor structure.

6. An apparatus as recited in claim 5:
wherein said single-gate has a pair of sidewalls; and
wherein charge-trapping regions are located along each of said sidewalls.

7. An apparatus as recited in claim 1, wherein said at least one charge-trapping region is configured for storing 4 bits of information.

8. An apparatus as recited in claim 7, wherein said transistor structure comprises a plurality of gate electrodes.

9. An apparatus as recited in claim 8:
wherein said at least one charge-trapping region is embedded in a gate dielectric stack underneath each gate electrode.

10. An apparatus as recited in claim 8:
wherein each gate electrode has a pair of sidewalls; and
wherein charge-trapping regions are located along each of said sidewalls of each gate electrode.

11. An apparatus as recited in claim 8, wherein said transistor structure includes symmetric double gates.

12. An apparatus as recited in claim 8, wherein said transistor structure includes asymmetric double gates.

13. An apparatus as recited in claim 8:
wherein said transistor structure comprises an undoped or lightly doped silicon film with thickness Tₛᵢ; and
wherein said double-gates have gate-length L_{g}.

14. An apparatus as recited in claim 8:
wherein said transistor structure includes an oxide layer underneath each charge-trapping region; and
wherein said oxide layer has a thickness sufficiently thin to allow for tunneling of electrons or holes from the silicon film into the charge-trapping region or from the charge-trapping region into the silicon film at relatively low voltages.

15. An apparatus, comprising:
a transistor structure;
said transistor structure having at least one gate electrode;
said transistor structure having at least one charge-trapping region;
wherein the at least one gate electrode and the at least one charge-trapping region are configured for storing 2 bits of information;
wherein off-state current is utilized to distinguish charge state of said bit in said transistor structure.

16. An apparatus as recited in claim 15:
wherein a bit state in the transistor structure is determined by off-state current; and
wherein a change in off-state current is utilized to determine a change in charge state of a bit in the charge-trapping region.

17. An apparatus as recited in claim 15, wherein a change in the off-state current arises from a change in transverse electric field due to stored charge.

18. An apparatus as recited in claim 15, wherein said transistor structure comprises a single-gate transistor structure.

19. An apparatus as recited in claim 15:
wherein each gate electrode has a pair of sidewalls; and
wherein a charge-trapping region is located along each of said sidewalls.

20. An apparatus, comprising:
a transistor structure;
said transistor structure having at least one gate electrode;
said transistor structure having at least one charge-trapping region;
wherein said at least one gate electrode and said at least one charge-trapping region are configured for storing 4 bits of information; and
wherein off-state current is utilized to distinguish charge state of said bit in said transistor structure.

21. An apparatus as recited in claim 20:
wherein a bit state in the transistor structure is determined by the transistor off-state current; and
wherein a change in off-state current is utilized to determine a change in charge state of a bit in the charge-trapping region.

22. An apparatus as recited in claim 20, wherein a change in the off-state current arises from a change in transverse electric field due to stored charge.

23. An apparatus as recited in claim 20, wherein said transistor structure comprises a plurality of gate electrodes.

24. An apparatus as recited in claim 23:
wherein said at least one charge-trapping region is embedded in a dielectric stack underneath each gate electrode.

25. An apparatus as recited in claim 23:
wherein each gate electrode has sidewalls; and
wherein said at least one charge-trapping region is embedded along each of said sidewalls.

26. An apparatus as recited in claim 23, wherein said transistor structure includes symmetric double gates.

27. An apparatus as recited in claim 23, wherein said transistor structure includes asymmetric double gates.

28. An apparatus as recited in claim 23:
wherein said transistor structure comprises an undoped or lightly doped silicon film with thickness Tₛᵢ; and
wherein said gate electrodes have gate-length L_{g}.

29. An apparatus as recited in claim 23:
wherein said transistor structure includes an oxide layer underneath each charge-trapping region; and
wherein said oxide layer has a thickness sufficiently thin to allow for tunneling of electrons or holes from the silicon film into the charge-trapping region or from the charge-trapping region into the silicon film at relatively low operating voltages.

30. An apparatus, comprising:
a transistor structure;
said transistor structure having at least one charge-trapping region;
wherein said transistor structure has a plurality of gate electrodes;
wherein said at least one charge-trapping region and said plurality of gate electrodes are configured for storing 4 bits of information; and
wherein off-state current is utilized to distinguish charge state of said bit in said transistor structure.

31. An apparatus as recited in claim 30:
wherein a bit state in the transistor structure is determined by off-state current; and
wherein a change in off-state current is utilized to determine a change in charge state of a bit in the charge-trapping region.

32. An apparatus as recited in claim 30, wherein a change in the off-state current arises from a change in transverse electric field due to stored charge.

33. An apparatus as recited in claim 30, wherein said transistor structure comprises a gate dielectric stack underneath each gate electrode.

34. An apparatus as recited in claim 33:
wherein said at least one charge-trapping region is embedded in said gate dielectric stack underneath each gate electrode.

35. An apparatus as recited in claim 30:
wherein each gate electrode has a pair of sidewalls; and
wherein said at least one charge-trapping region is located along each of said sidewalls of each gate electrode.

36. An apparatus as recited in claim 30, wherein said transistor structure includes symmetric double gates.

37. An apparatus as recited in claim 30, wherein said transistor structure includes asymmetric double gates.

38. An apparatus as recited in claim 30:
wherein said transistor structure comprises an undoped or lightly doped silicon film with thickness Tₛᵢ; and
wherein said gate electrodes have gate-length L_{g}.

39. An apparatus as recited in claim 30:
wherein said transistor structure includes an oxide layer underneath each charge-trapping region; and
wherein said oxide layer has a thickness sufficiently thin to allow for tunneling of electrons or holes from the silicon film into the charge-trapping region or from the charge-trapping region into the silicon film at relatively low operating voltages.
